(19) United States
(12) Patent Application Publication
(10) Pub. No.: US 2011/0091820 A1
(43) Pub. Date: Apr. 21, 2011

(54) RESIST PROCESSING METHOD

(76) Inventors: Mitsuhiro Hata, Delmar, NY (US); Takashi Hiraoka, Osaka (JP); Junji Shigematsu, Osaka (JP)

(21) Appl. No.: 12/999,300

(22) PCT Filed: Jun. 10, 2009
(86) PCT No.: PCT/JP2009/060606

§ 371 Date: Jan. 6, 2011

(30) Foreign Application Priority Data
Jun. 16, 2008 (JP) 2008-157130

(51) Int. Cl. G03F 7/20

(52) U.S. Cl. 430/325

(57) ABSTRACT

A resist processing method has: (1) a step of applying a first resist composition comprising a resin (A) having an acid-labile group, being insoluble or poorly soluble in alkali aqueous solution, and being rendered soluble in alkali aqueous solution through an action of an acid, a photo acid generator (B) and a cross-linking agent (C) to obtain a first resist film; (2) a step of prebaking the first resist film; (3) a step of exposure processing the first resist film; (4) a step of post-exposure baking the first resist film; (5) a step of developing with a first alkali developer to obtain a first resist pattern; (6) a step of hard-baking by maintaining the first resist pattern at a temperature which is lower than a glass transition temperature of the above-mentioned first resist composition for a predetermined period of time, and then maintaining the first resist pattern at a temperature which is the glass transition temperature of the first resist composition or higher for a predetermined period of time; (7) a step of applying a second resist composition onto the first resist pattern, and then drying to obtain a second resist film; (8) a step of pre-baking the second resist film; (9) a step of exposure processing the second resist film; (10) a step of post-exposure baking the second resist film; and (11) a step of developing with a second alkali developer liquid to obtain a second resist pattern.

### TECHNICAL FIELD

The present invention relates to a resist processing method, and in more derail, relates to a resist processing method used for the formation of a micro resist pattern through a double patterning method and a double imaging method.

### BACKGROUND ART

In recent years, there is an increasing demand for miniaturization of micro-processing for semiconductors using lithographic techniques. A double patterning method (for example, JP-2007-311508-A) and a double imaging method (for example, Proceedings of SPIE. Vol. 6520, 65202F (2007)) have been proposed as processes that realize a line width of a resist pattern of 32 nm or less.

A double patterning method as used herein represents a method which uses double the spacing of the target resist pattern to execute normal exposure, developing and etching steps thereby executing a first transcription and then, in the resulting space, executes again the same exposure, developing and etching steps thereby executing a second transcription, and realize the target micro resist pattern. A double imaging method is a method which uses double the spacing of the target resist pattern to execute normal exposure, developing steps, and processes the resist pattern using a chemical solution termed a freezing agent, thereafter, executes again the same exposure and developing in the space thereby realizing the target micro resist pattern.

### DISCLOSURE OF THE INVENTION

### Problem to be Solved

The present invention has the object of providing a method of resist processing that enables a double patterning method or a double imaging method.

A resist processing method comprises

(1) a step of applying a first resist composition comprising a resin (A) having an acid-labile group, being insoluble or poorly soluble in alkali aqueous solution, and being rendered soluble in alkali aqueous solution through an action of an acid, a photo acid generator (B) and a cross-linking agent (C) to obtain a first resist film;

(2) a step of prebaking the first resist film;

(3) a step of exposure processing the first resist film;

(4) a step of post-exposure baking the first resist film;

(5) a step of developing with a first alkali developer to obtain a first resist pattern;

(6) a step of hard-baking by maintaining the first resist pattern at a temperature which is lower than a glass transition temperature of the above-mentioned first resist composition for a predetermined period of time, and then maintaining the first resist pattern at a temperature which is the glass transition temperature of the first resist composition or higher for a predetermined period of time;

(7) a step of applying a second resist composition onto the first resist pattern, and then drying to obtain a second resist film;

(8) a step of pre-baking the second resist film;

(9) a step of exposure processing the second resist film;

(10) a step of post-exposure baking the second resist film; and

(11) a step of developing with a second alkali developer liquid to obtain a second resist pattern.

According to the resist processing method, it is preferably that one or more of below a. to h. includes;

a. the first resist pattern is maintained at a temperature which is lower than the glass transition temperature for 60 seconds or more, or the maintaining the first resist pattern at a temperature which is lower than the glass transition temperature is performed at a constant temperature;

b. the cross-linking agent (C) is at least one selected from the group consisting of a urea cross-linking agent, an alkylene urea cross-linking agent and a glycoluril cross-linking agent;

c. the content of the cross-linking agent (C) is 0.5 to 30 parts by mass relative to the resin (A) 100 parts by mass;

d. the acid-labile group of the resin (A) is a group having an alkyl ester group or lactone ring, in which a carbon atom that bonds to an oxygen atom of —COO— is a quaternary carbon atom, or a group having a carboxylate;

e. the resist processing method according to any one of claims 1 to 6, wherein the photo acid generator (B) is a compound represented by the formula (I);

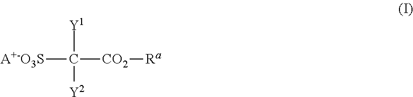

wherein, R^{a} is a C₁ to C₆ linear or branched chain hydrocarbon group, or a C₃ to C₃₀ cyclic hydrocarbon group, when R^{a} is a cyclic hydrocarbon group, the cyclic hydrocarbon group may be substituted with one or more selected from the group consisting of a C₁ to C₆ alkyl group, a C₁ to C₆ alkoxy group, a C₁ to C₄ perfluoroalkyl group, an ether group, an ester group, a hydroxyl group and a cyano group;

A⁺ represents an organic counter ion; and

Y¹ and Y² independently represent a fluorine atom or a C₁ to C₆ perfluoroalkyl group.

f. the resist processing method according to any one of claims 1 to 7, wherein the photo acid generator (B) is a compound represented by the formula (V) or the formula (VI);

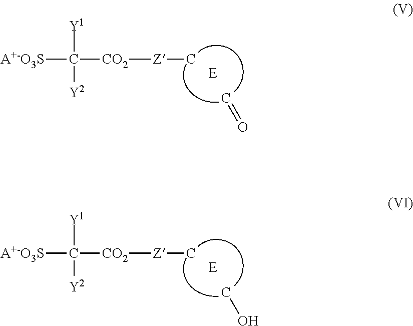

wherein a ring E represents a C₃ to C₃₀ cyclic hydrocarbon group, the ring E may be substituted with one or more selected from the group consisting of a C₁ to C₆ alkyl group, a C₁ to C₆ alkoxy group, a C₁ to C₄ perfluoroalkyl group, a C₁ to C₆ hydroxyalkyl group, a hydroxyl group and a cyano group;

Z′ represents a single bond or a C₁ to C₄ alkylene group; and

A⁺, Y¹ and Y² have the same meaning as defined above.

g. the resist processing method according to any one of claims 1 to 8, wherein the photo acid generator (B) is a compound containing one or more cations selected from the group consisting of the formulae (IIa), (IIb), (IIc), (IId) and (IV);

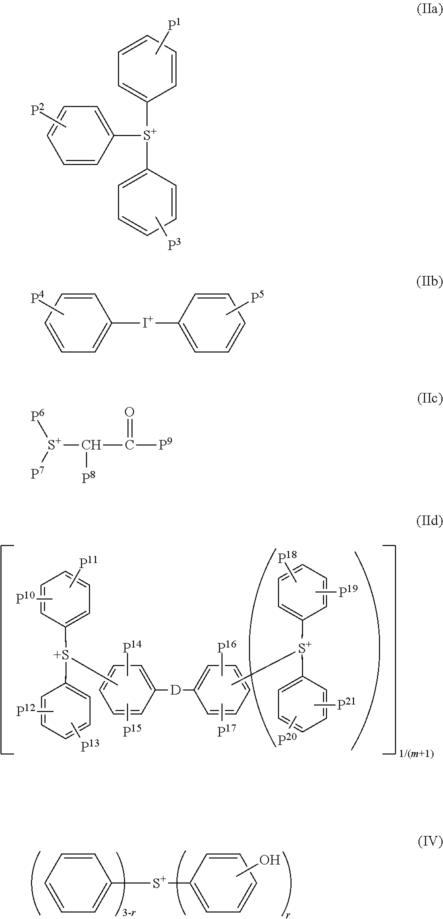

wherein P¹ to P⁵ and P⁵ to P¹⁰ and P²¹ independently represent a hydrogen atom, a hydroxyl group, a C₁ to C₁₂ alkyl group or a C₁ to C₁₂ alkoxy group;

P⁶ and P⁷ independently represent a C₁ to C₁₂ alkyl group or a C₃ to C₁₂ cycloalkyl group, or P⁶ and P⁷ are bonded to represent a C₃ to C₁₂ divalent hydrocarbon group;

P⁸ represents a hydrogen atom;

P⁹ represents a C₁ to C₁₂ alkyl group, a C₃ to C₁₂ cycloalkyl group or an optionally substituted aromatic group, or P⁸ and P⁹ are bonded to represent a C₃ to C₁₂ divalent hydrocarbon group;

D represents a sulfur atom or an oxygen atom; and

m represents 0 or 1; and

r represents an integer of 1 to 3.

h. the resist processing method of according to any one of claims 1 to 9, which further comprises a thermal acid generator (D).

### Effect of the Invention

According to the method of resist processing of the present invention, double patterning method and a double imaging method are enabled, that is, a first-layer resist pattern can be formed in a desire shape more accurately with reliability, as well as by processing of the second and subsequent layers, maintenance of the shape of the first-layer resist pattern without deforming it enables. As a result, an extremely fine pattern can be formed.

### DETAILED DESCRIPTION OF THE PREFERRED EMBODIMENTS

The resist composition used for the resist processing method of the present invention mainly comprises a resin (A), a photo acid generator (B) and a cross-linking agent (C), and, in particular, it is characterized in that the cross-linking agent (C) is contained therein.

The resin in such resist composition has an acid-labile group, and prior to exposure, is insoluble or poorly soluble in an alkali aqueous solution, the resin can be dissolved in an alkali aqueous solution as a result of cleaving through the catalytic action on the acid-labile group in the resin by acid produced from the photo acid generator (B) during exposure. Meanwhile, in unexposed portions of the resin, alkali insolubility characteristics are retained. In this manner, the resist composition enables formation of a positive-type resist pattern by subsequent development using an alkali aqueous solution. Here, “insoluble or poorly soluble in alkali aqueous solution” means a solubility requiring about 100 mL or more of alkali aqueous solution generally used as a developer, in order to dissolve generally 1 g or 1 mL of the resist composition of the present invention, although this can vary, depending on the alkali aqueous solution type, concentration, and the like. “Soluble in alkali aqueous solution” means soluble enough that less than 100 mL alkali aqueous solution is sufficient to dissolve 1 g or 1 mL of the resist composition.

The acid-labile group in the resin (A) represents a group which undergoes cleavage or tends to undergo cleavage as described above by an acid produced from the photo acid generator (B) described below. There is no particular limitation on the group as long as the group includes such properties.

For example, examples include;

a group having an alkyl ester group in which a carbon atom that bonds to the oxygen atom of —COO— is a quaternary carbon atom;

a group having a lactone ring in which a carbon atom that bonds to the oxygen atom of —COO— is a quaternary carbon atom;

a group having a carboxylate such as acetal type ester and alicyclic ester. Among these, a group giving a carboxyl group is preferred due to the action of the acid which is produced from the photo acid generator (B) described below. A quaternary carbon atom as used herein means a carbon atom which bonds with a substituent other than a hydrogen atom and does not bond with hydrogen atom. In particular, it is preferably a quaternary carbon atom in which the carbon atom that bonds to an oxygen atom of —COO— is bonded to three carbon atoms.

When a group having carboxylate, which is one of the acid-labile group, is exemplify as “R ester of —COOR”, examples include an alkyl ester in which a carbon atom that bonds to the oxygen atom of —COO— is a quaternary carbon atom such as a tert-butyl ester group, i.e., “—COO—C(CH₃)₃”;

an acetal type ester group or lactone ring-containing group, such as methoxymethyl ester, ethoxymethyl ester, 1-ethoxyethyl ester, 1-isobutoxyethyl ester, 1-isopropoxyethyl ester, 1-ethoxypropyl ester, 1-(2-methoxyethoxy)ethyl ester, 1-(2-acetoxyethoxy)ethyl ester, 1-[2-(1-adamantyloxy)ethoxy]ethyl ester, 1-[2-(1-adamantanecarbonyloxy)ethoxy]ethyl ester, tetrahydro-2-furyl ester and tetrahydro-2-pyranyl ester group;

an alicyclic ester group in which a carbon atom bonding to the oxygen atom of —COO— is quaternary carbon atom, such as an isobornyl ester, 1-alkylcycloalkyl ester, 2-alkyl-2-adamantyl ester and 1-(1-adamantyl)-1-alkylalkyl ester group.

Examples of such group having an carboxylate include a group having (meth)acrylate, norbornene carboxylate, tricyclodecene carboxylate, tetracyclodecene caroxylate.

The resin (A) can be produced by addition polymerization of a monomer having a group which is unstable relative to an acid and which includes olefinic double bonds.

Monomers having a bulky group such as an alicyclic structure, in particular, a bridged structure as an acid-labile group (e.g. a 2-alkyl-2-adamantyl group and 1-(1-adamantyl)-1-alkylalkyl group) are preferable, since resolution of the obtained resist has a tendency to be excellent. Examples of such monomer containing the bulky group include a 2-alkyl-2-adamantyl(meth)acrylate, a 1-(1-adamantyl)-1-alkylalkyl(meth)acrylate, a 2-alkyl-2-adamantyl 5-norbornene-2-carboxylate, a 1-(1-adamantyl)-1-alkylalkyl 5-norbornene-2-carboxylate.

Particularly, using the 2-alkyl-2-adamantyl(meth)acrylate as the monomer is preferable because a resist composition having excellent resolution tends to be obtained.

Examples of the 2-alkyl-2-adamantyl(meth)acrylate include 2-methyl-2-adamantyl acrylate, 2-methyl-2-adamantyl methacrylate, 2-ethyl-2-adamantyl acrylate, 2-ethyl-2-adamantyl methacrylate, 2-isopropyl-2-adamantyl acrylate, 2-isopropyl-2-adamantyl methacrylate and 2-n-butyl-2-adamantyl acrylate.

Among these, 2-ethyl-2-adamantyl(meth)acrylate or 2-isopropyl-2-adamantyl(meth)acrylate is preferably used because a resist composition having excellent sensitivity and heat resistance tends to be obtained.

The 2-alkyl-2-adamantyl(meth)acrylate can be usually produced by reacting a 2-alkyl-2-adamantanol or a metal salt thereof with an acrylic halide or a methacrylic halide.

One characteristic of the resin (A) used in the present invention is that it includes structural units having high-polarity substituents. This type of structural unit includes a structural unit derived from a substance in which one or more hydroxyl groups are bonded to 2-norbornene, a structural unit derived from (meth)acrylonitrile, a structural unit derived from a substance in which one or more hydroxyl groups are bonded and that is a type of (meth)acrylic esters such as 1-adamantyl ester or an alkyl ester in which a carbon atom which bonds to an oxygen atom of —COO— is a secondary carbon atom or a tertiary carbon atom, a structural unit derived from a styrene monomer such as p- or m-hydroxystrene, a structural unit derived from (meth)acryloyloxy-γ-butyrolactone in which the lactone ring may be substituted with an alkyl group. A 1-adamantyl ester, in which the carbon atom which bonds to an oxygen atom of —COO— is quaternary atoms, is a group which is stable to an acid.

Specific examples of the monomer having the high-polarity substituent include 3-hydroxy-1-adamantyl(meth)acrylate; 3,5-dihydroxy-1-adamantyl(meth)acrylate; α-(meth)acryloyloxy-γ-butyrolactone; β-(meth)acryloyloxy-γ-butyrolactone; a monomer represented by the formula (a) below, a monomer represented by the formula (b), and hydroxystyrene.

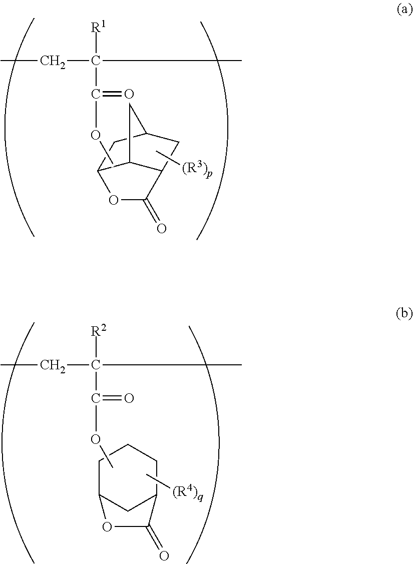

wherein R¹ and R² independently represent a hydrogen atom or a methyl group;

R³ and R⁴ independently represent a hydrogen atom, a methyl group or a trifluoromethyl or a halogen atom;

p and q represent an integer of 1 to 3, when p is 2 or 3, the plurality of R³ may be the different from each other, when q is 2 or 3, the plurality of R⁴ may be different from each other.

Among these, the resist obtained from a resin having any of a structural unit derived from 3-hydroxy-1-adamantyl(meth)acrylate, the structural unit derived from 3,5-dihydroxy-1-adamantyl(meth)acrylate, the structural unit derived from α-(meth)acryloyloxy-γ-butyrolactone, the structural unit derived from [3-(meth)acryloyloxy-γ-butyrolactone, the structural unit represented by the formula (a), and the structural unit represented by the formula (b) is preferable because improvement of the adhesiveness of resist to a substrate and resolution of resist tends to be obtained. A 1-adamantyl ester, in which the carbon atom which bonds to an oxygen atom of —COO— is quaternary atoms, is a group which is stable to an acid.

The resin (A) used in the present invention may include other structural units. Structural units include a structural unit derived from a monomer having a free carboxylic group such as acrylic acid or methacrylic acid, a structural unit derived from an aliphatic unsaturated dicarboxylic anhydride such as maleic anhydride, itaconic anhydride, a structural unit derived from 2-norbornene, a structural unit derived from (meth)acrylic esters such as an 1-adamantyl ester or alkyl ester in which a carbon atom which bonds to an oxygen atom of —COO— is a secondary carbon atom or a tertiary carbon atom.

3-Hydroxy-1-adamantyl(meth)acrylate and 3, 5-dihydroxy-1-adamantyl (meth)acrylate are commercially available, but they can also be produced, for example, by reacting a corresponding hydroxyadamantane with (meth)acrylic acid or its acid halide.

A monomer such as (meth)acryloyloxy-γ-butyrolactone can be produced by reacting α- or β-bromo-γ-butyrolactone in which the lactone ring may be substituted with a alkyl group with acrylic acid or methacrylic acid, or reacting α- or β-hydroxy-γ-butyrolactone in which the lactone ring may be substituted with a alkyl group with an acrylic halide or a methacrylic halide.

Monomers to give structural units represented by the formula (a) and the formula (b) include a (meth)acrylate of an alicyclic lactone having the hydroxyl group described below, and mixtures thereof. These esters can be produced, for example, by reacting a corresponding alicyclic lactone having the hydroxyl group with (meth)acrylic acid (see, for example, JP 2000-26446 A).

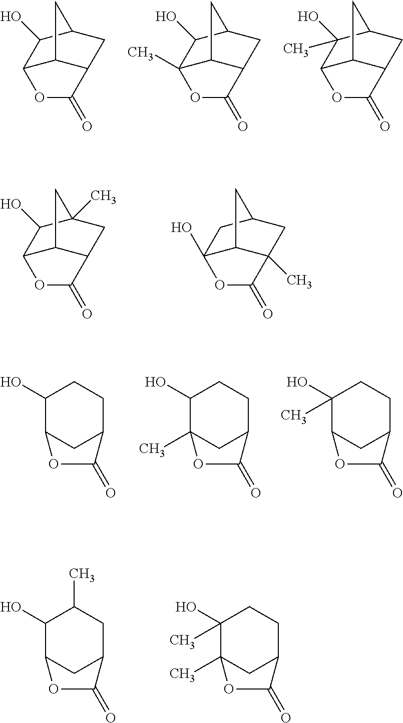

Examples of the (meth)acryloyloxy-γ-butyrolactone include α-acryloyloxy-γ-butyrolactone, a-methacryloyloxy-γ-butyrolactone, α-acryloyloxy-β,β-dimethyl-γ-butyrolactone, α-methacryloyloxy-β,β-dimethyl-γ-butyrolactone, α-acryloyloxy-α-methyl-γ-butyrolactone, α-methacryloyloxy-α-methyl-γ-butyrolactone, β-acryloyloxy-γ-butyrolactone, β-methacryloyloxy-γ-butyrolactone and β-methacryloyloxy-α-methyl-γ-butyrolactone.

In the case of KrF excimer laser exposure, sufficient transmittance can be obtained even the structural unit derived from a styrene monomer such as p- or m-hydroxystrene is used as the structural unit of the resin. Such resin can be obtained by radical-polymerizing with (meth)acrylic ester monomer, acetoxystyrene and styrene, and then de-acetylating with an acid.

The resin having a structural unit derived from 2-norbornene results in a sturdy structure because the main chain directly has an alicyclic backbone and allow dry etching resistance. The structural unit derived from 2-norbornene can be introduced into the main chain, for example, by radical polymerization with the combined use of an aliphatic unsaturated dicarboxylic anhydride such as maleic anhydride or itaconic anhydride in addition to the corresponding 2-norbornene. Accordingly, the structural unit formed upon the opening of the double bond in the norbornene structure can be represented by the formula (c), whereas structural unit formed upon the opening of the double bond of maleic anhydride and itaconic anhydride can be represented by the formulas (d) and (e), respectively.

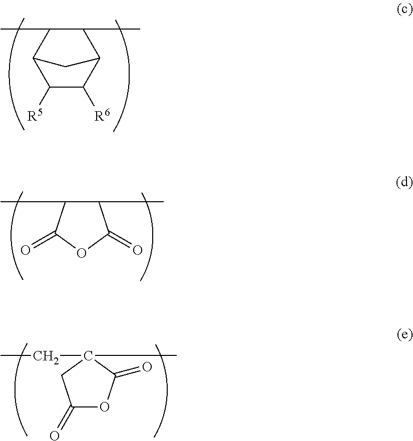

wherein R⁵ and/or R⁶ independently represent a hydrogen atom, a C₁ to C₃ alkyl group, a carboxyl group, a cyano group, or —COOU wherein U is an alcohol residue, or R⁵ and R⁶ can be bonded together to form a carboxylic anhydride residue represented by —C(═O)OC(═O)—.

When R⁵ and/or R⁶ is —COOU group, it is an ester formed from carboxyl group. Examples of the alcohol residue corresponding to U include an optionally substituted C₁ to C₈ alkyl group, and 2-oxooxolan-3- or -4-yl group. The alkyl group may be substituted with a hydroxyl group or an alicyclic hydrocarbon group.

Examples of the alkyl group include methyl group, ethyl group, n-propyl group, iso-propyl group, n-butyl group, sec-butyl group, tert-butyl group, pentyl group, hexyl group, octyl group and 2-ethylhexyl group.

Examples of the alkyl group substituted with a hydroxyl group, i.e., a hydroxylalkyl group include hydroxylmethyl group and 2-hydroxylethyl group.

Examples of the alicyclic hydrocarbon group include the alicyclic hydrocarbon group having about 3 to 30 carbon atoms, such as cyclopropyl, cyclobutyl, cyclopentyl, cyclohexyl, cycloheptyl, cyclodecyl, cyclohexenyl, bicyclobutyl, bicyclohexyl, bicyclooctyl and 2-norbonyl.

In the present specification, groups described above such as an alkyl group are exemplary of similar entities as described above in any of the chemical formulae, which may differ relative to the number of carbon atoms, unless otherwise specified.

Furthermore when a group enables both linear and branched chain structures, both structures are included (the same applies hereinafter).

The followings can be specific examples of the norbornene structures represented by the formula (c), which are monomers giving an acid-stable group.

2-norbornene,

2-hydroxy-5-norbornene,

5-norbornene-2-carboxylic acid,

methyl 5-norbornene-2-carboxylate,

2-hydroxy-1-ethyl 5-norbornene-2-carboxylate,

5-norbornene-2-methanol, and

5-norbornene-2,3-dicarboxylic acid anhydride.

When the U of the —COOU of R⁵ and/or R⁶ in the formula (c) is an acid-labile group, such as an aliphatic ester in which a carbon atom bonded to the oxygen atom of —COO— is quaternary carbon atom, the group will be a structure unit having an acid-labile group, despite having a norbornene structure.

Examples of the monomer having a norbornene structure and an acid-labile group include t-butyl 5-norbornene-2-carboxylate, 1-cyclohexyl-1-methylethyl 5-norbornene-2-carboxylate, 1-methylcyclohexyl-5-norbornene-2-carboxylate, 2-methyl-2-adamantyl 5-norbornene-2-carboxylate, 2-ethyl-2-adamantyl 5-norbornene-2-carboxylate, 1-(4-methylcyclohexyl)-1-methylethyl 5-norbornene-2-carboxylate, 1-(4-hydroxycyclohexyl)-1-methylethyl 5-norbornene-2-carboxylate, 1-methyl-1-(4-oxocyclohexyl)ethyl 5-norbornene-2-carboxylate and 1-(1-adamantyl)-1-methylethyl 5-norbornene-2-carboxylate.

The resin (A) used in the present resist composition preferably contains structural unit(s) derived from a monomer having an acid-labile group generally in a ratio of 10 to 80 mol% in the resin (A) though the ratio varies depending on the kind of radiation for patterning exposure, the kind of an acid-labile group, and the like.

When the structural unit derived from 2-alkyl-2-adamantyl(meth)acrylate or 1-(1-adamantyl)-1-alkylalkyl(meth)acrylate in particular is included as the structural unit derived from the monomer with the acid-labile group, adjusting the content to 15 mol% or more with respect to the total structural units constituting the resin is advantageous in terms of the dry etching resistance of the resulting resist because the resin will have an alicyclic group and will be a sturdy structure.

When an alicyclic compound and an aliphatic unsaturated dicarboxylic anhydride having an olefinic double bond in its molecule are used as the monomer, they are preferably used in excess amounts from the viewpoint of a tendency that the addition polymerization does not easily proceed.

Further, as the monomers that are used, monomers that have the same olefinic double bond moieties but different acid-labile group may be used in combination, combinations of monomers with the same acid-labile groups and different olefinic double bond moieties may be used in combination, and combinations of monomers with different combinations of acid-labile groups and olefinic double bond moieties may be used in combination.

There is no particular limitation on the photo acid generator (B) as long as it is one producing an acid by exposure, and any known substance in this technical field may be used.

For example, compounds represented by formula (I) may be used as the photo acid generator (B).

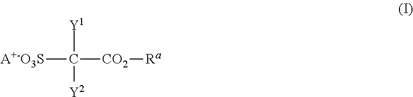

wherein, R^{a} is a C₁ to C₆ linear or branched chain hydrocarbon group, or a C₃ to C₃₀ cyclic hydrocarbon, when R^{a} is a cyclic hydrocarbon group, the cyclic hydrocarbon group may be substituted with at least one selected from the group consisting of a C₁ to C₆ alkyl group, a C₁ to C₆ alkoxy group, a C₁ to C₄ perfluoroalkyl group, an ether group, an ester group, a hydroxyl group and a cyano group;

A⁺ represents an organic counter ion;

Y¹ and Y² independently represent a fluorine atom or a C₁ to C₆ perfluoroalkyl group.

Here, the hydrocarbon may be the same as the alkyl group described above and may a group introduced at least one double bond or triple bond into any site on the alkyl group. Among these, an alkyl group is preferred.

A C₃ to C₃₀ cyclic hydrocarbon group may or may not be an aromatic group. The hydrocarbon group includes a monocyclic or a bicyclic hydrocarbon group, an aryl or an aralkyl group. More specifically, in addition to the alicyclic hydrocarbon group described above such as a C₄ to C₈ cycloalkyl or norbornyl, other examples include phenyl, indenyl, naphthyl, adamantyl, norbornenyl, tolyl and benzyl.

Examples of the alkoxyl group include methoxy, ethoxy, n-propoxy, isopropoxy, n-butoxy, sec-butoxy, tert-butoxy, pentoxy, hexoxy, octyloxy and 2-ethylhexyloxy groups.

Examples of the perfluoroalkyl group include perfluoromethyl, perfluoroethyl, perfluoropropyl and perfluorobutyl.

The photo acid generator (B) may be a compound represented by the formula (V) or the formula (VI).

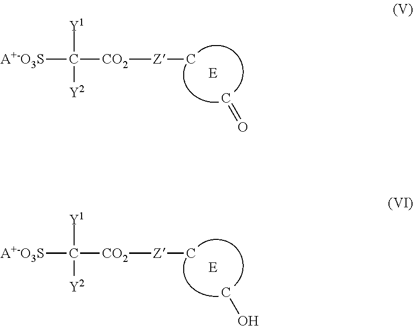

wherein a ring E represents an C₃ to C₃₀ cyclic hydrocarbon group, the ring E may be substituted with at least one selected from the group consisting of a C₁ to C₆ alkyl group, a C₁ to C₆ alkoxy group, a C₁ to C₄ perfluoroalkyl group, a C₁ to C₆ hydroxyalkyl group, a hydroxyl group and a cyano group;

Z′ represents a single bond or a C₁ to C₄ alkylene group;

A⁺, Y¹ and Y² have the same meaning as defined above.

Examples of an alkylene group include the following groups represented by (Y-1) to (Y-12).

The photo acid generator (B) may be a compound represented by the formula (III).

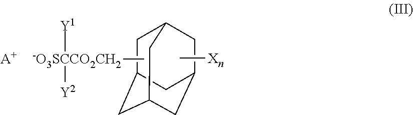

wherein Y¹ and Y² independently represent a fluorine atom or a C₁ to C₆ perfluoroalkyl group;

X represents —OH or —Y—OH, Y represents C₁ to C₆ linear or branched chain alkylene group;

n represents an integer of 1 to 9;

A⁺ has the same meaning as defined above.

Y¹ or Y² is preferably a fluorine atom.

n is preferably an integer of 1 to 2.

Examples of the Y include, for example, the following groups represented by (Y-1) to (Y-12). Among there, (Y-1) and (Y-2) are preferable due to their ease of production.

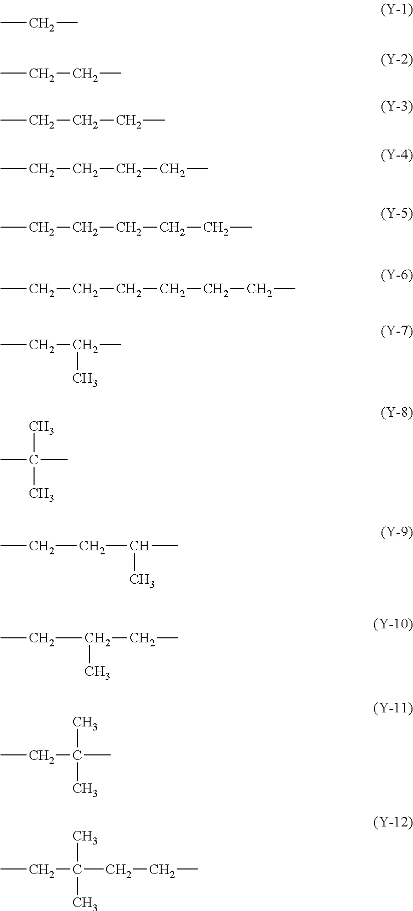

Examples of the anion in the compound represented by the formula (I), (III), (V) or (VI) include the following compounds.

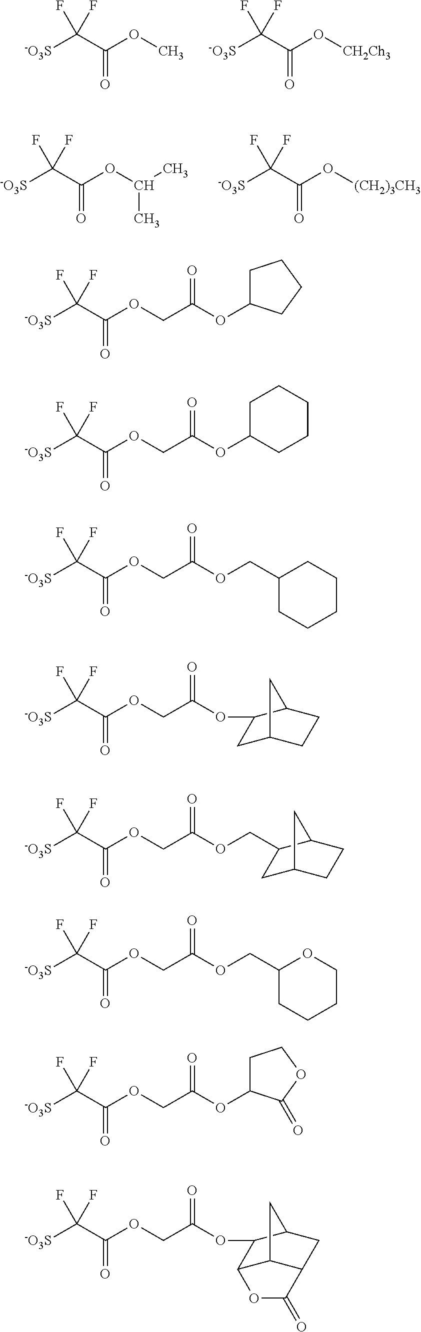

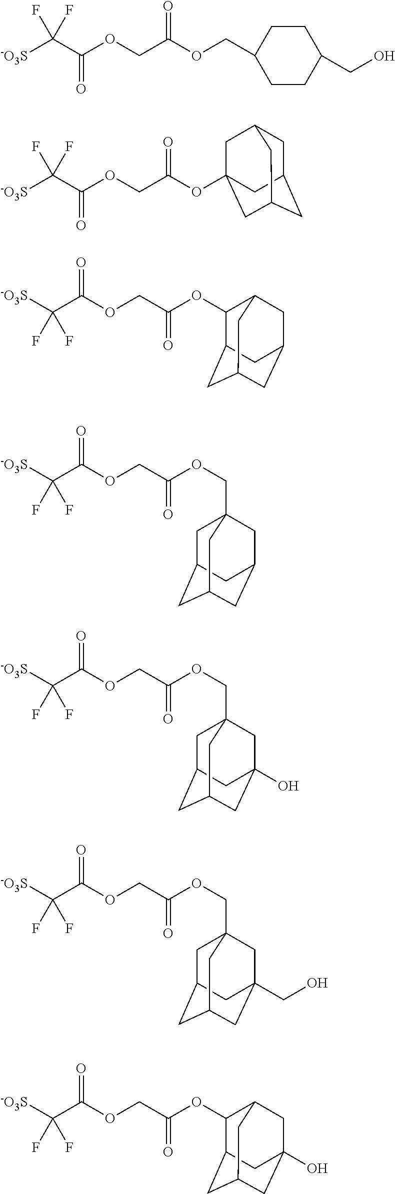

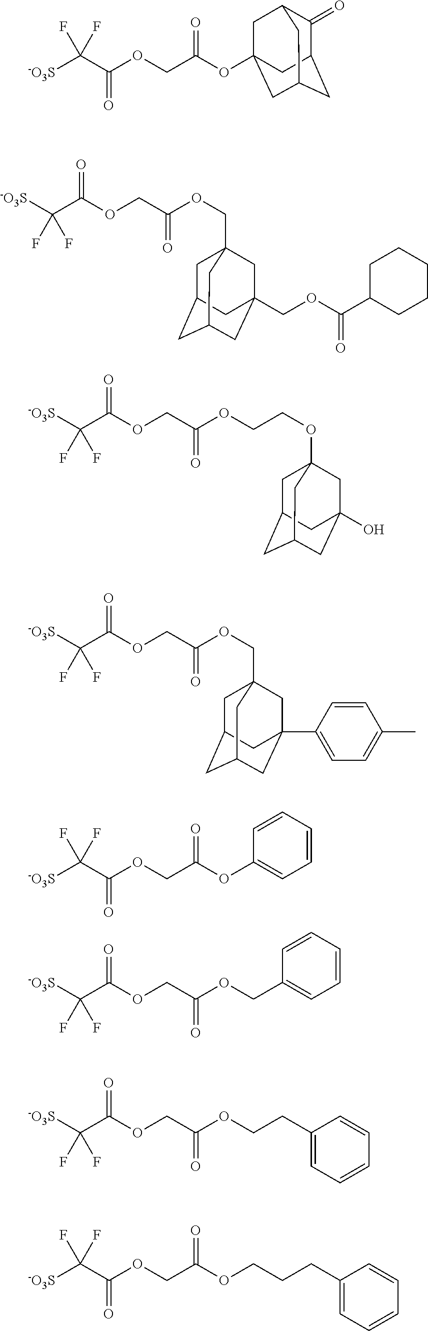

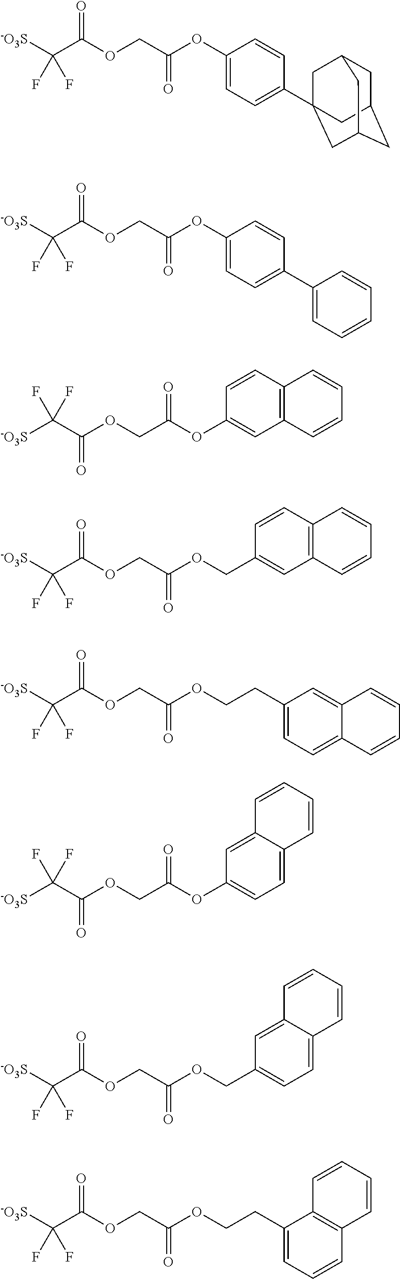

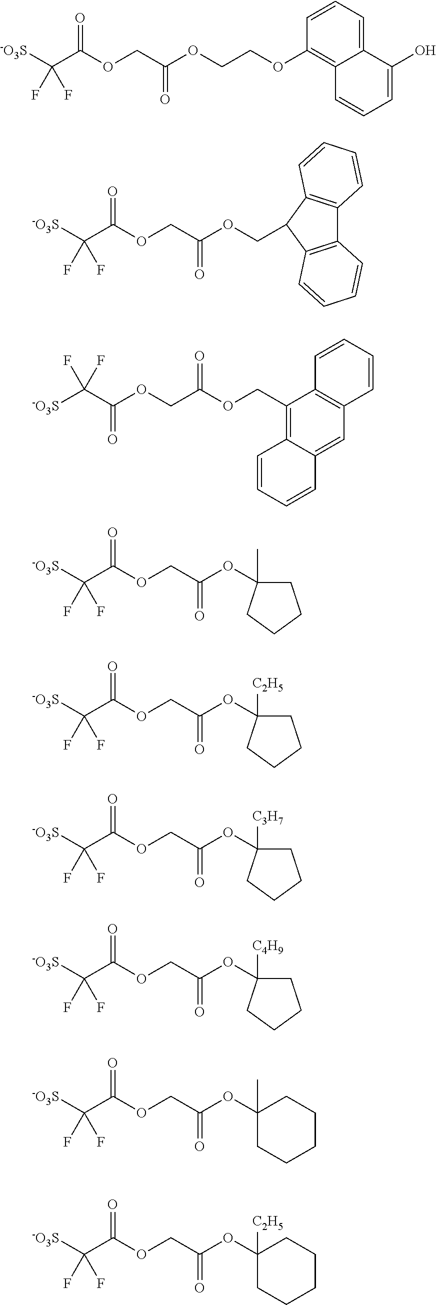

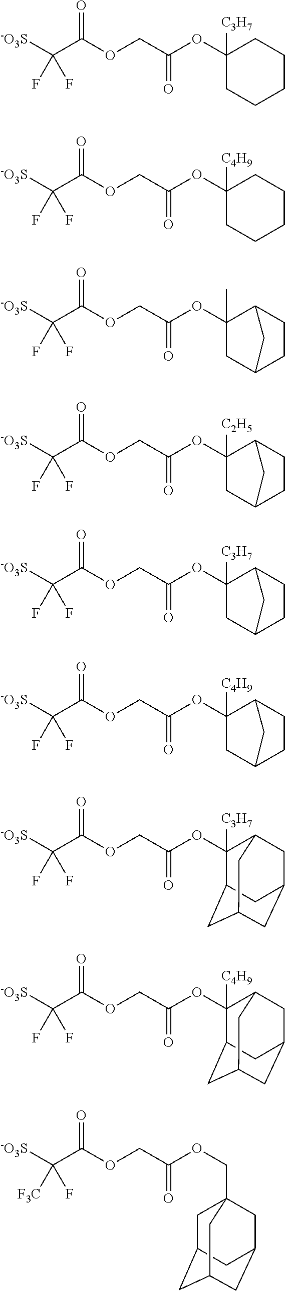

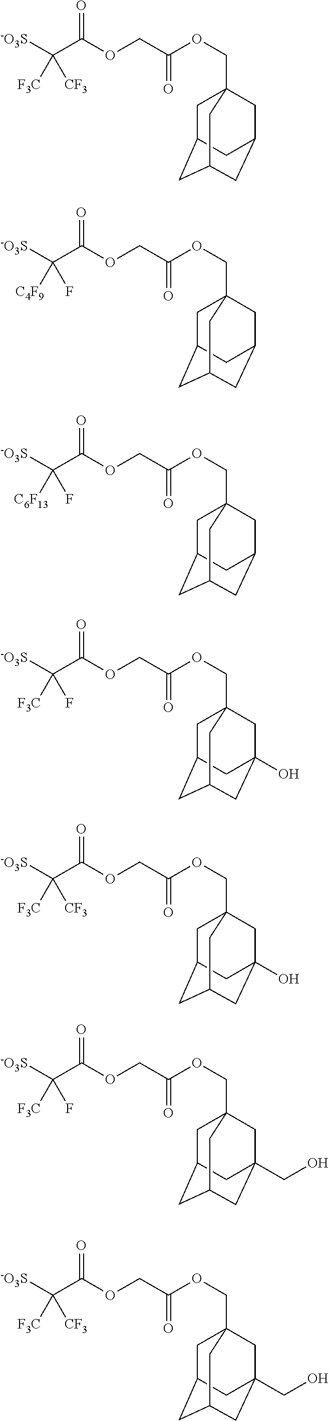

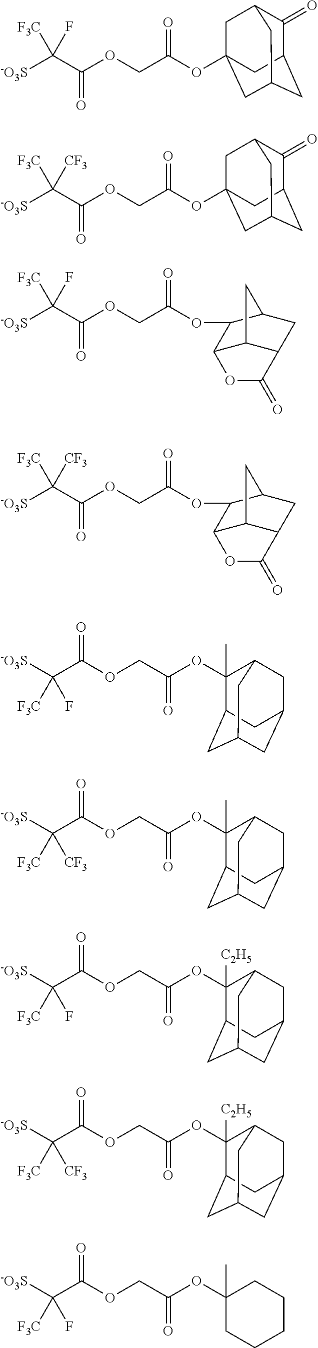

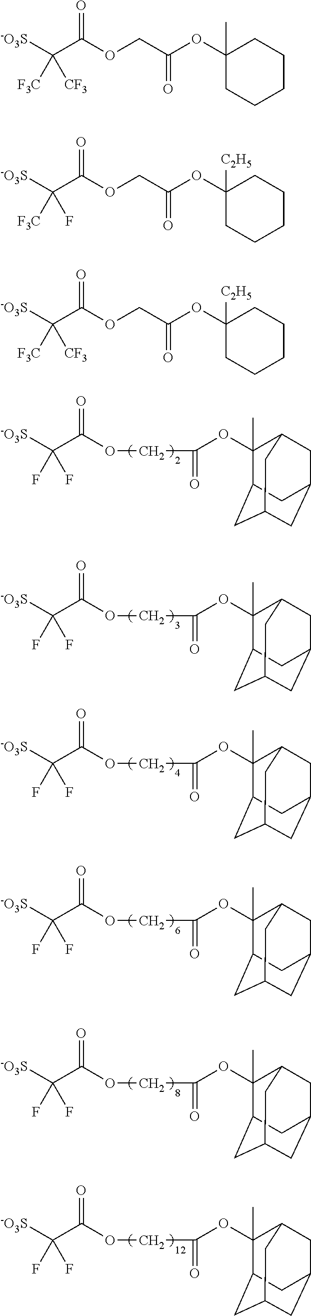

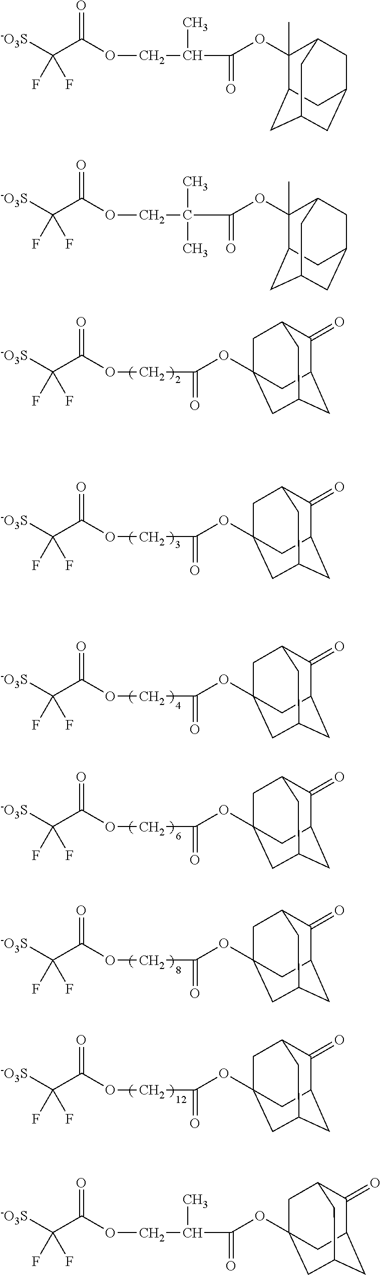

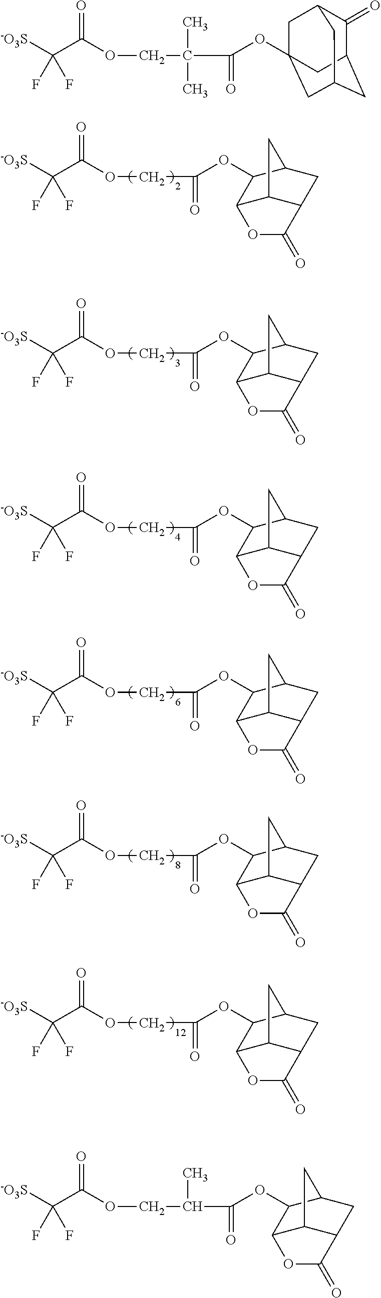

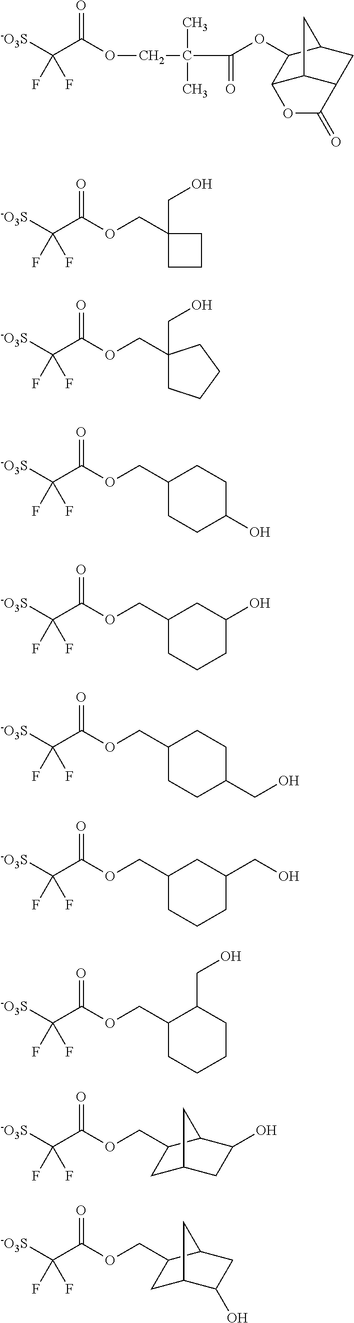

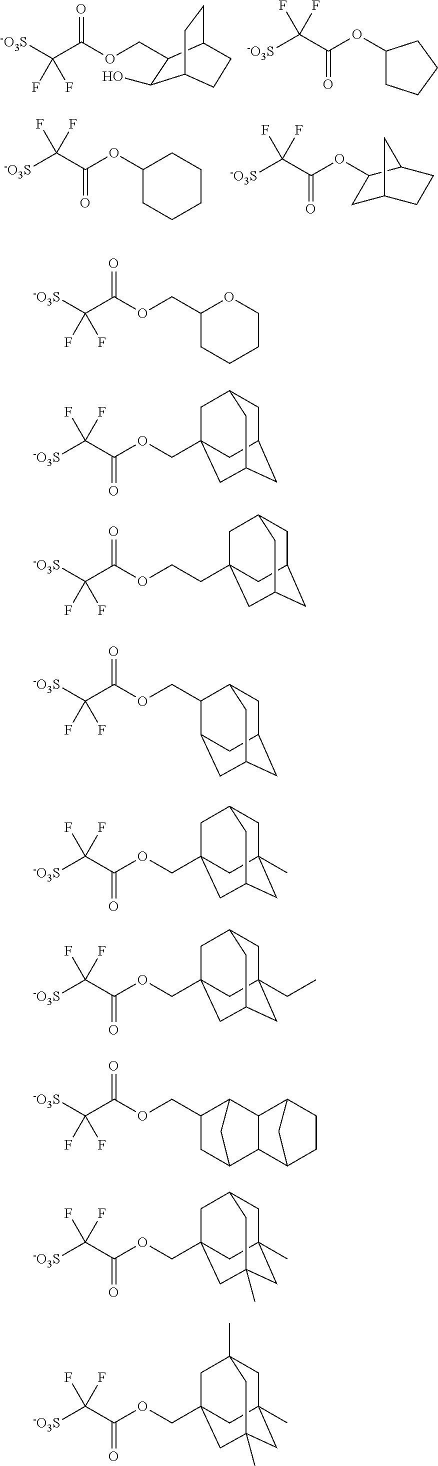

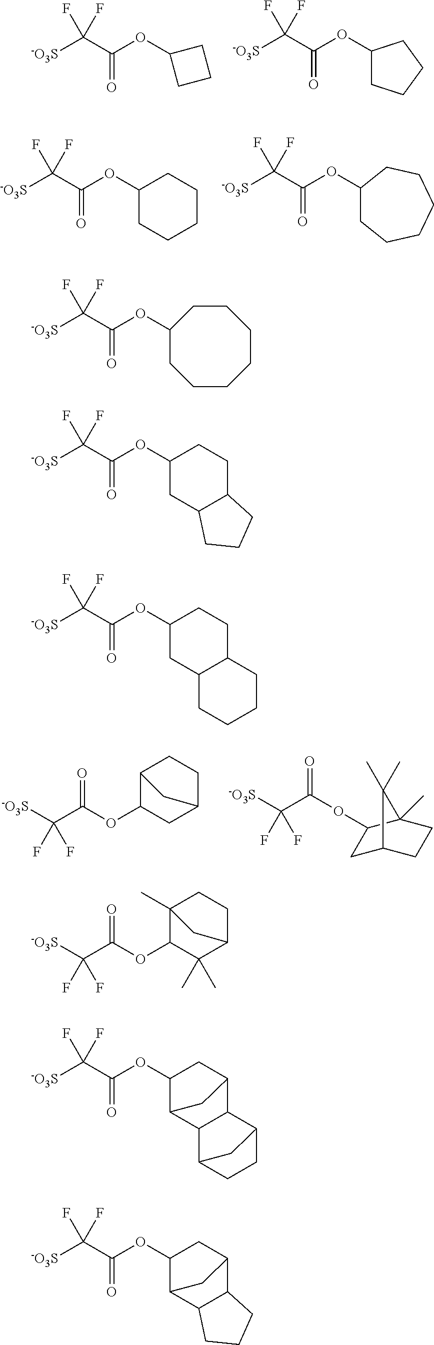

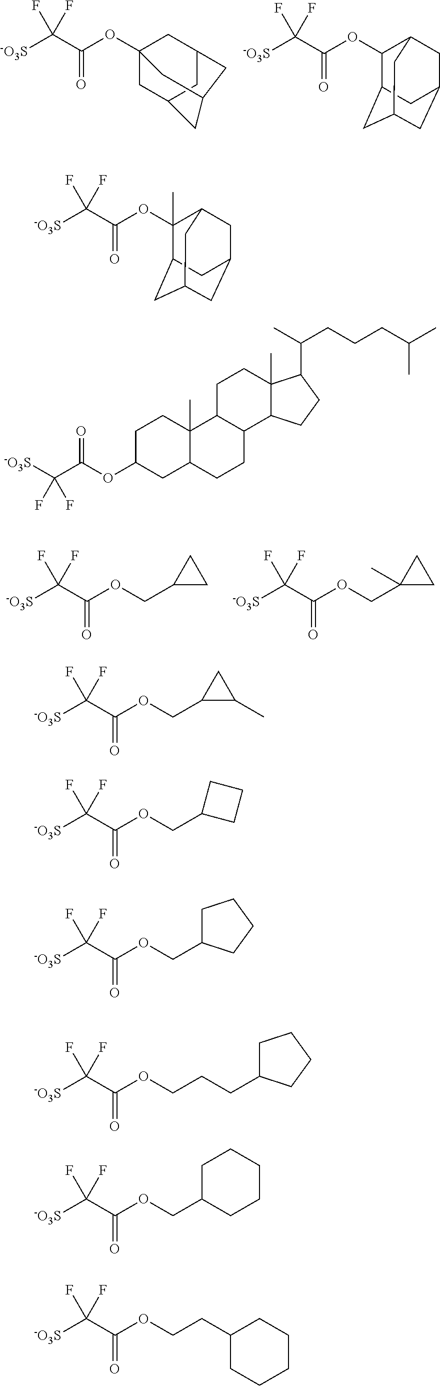

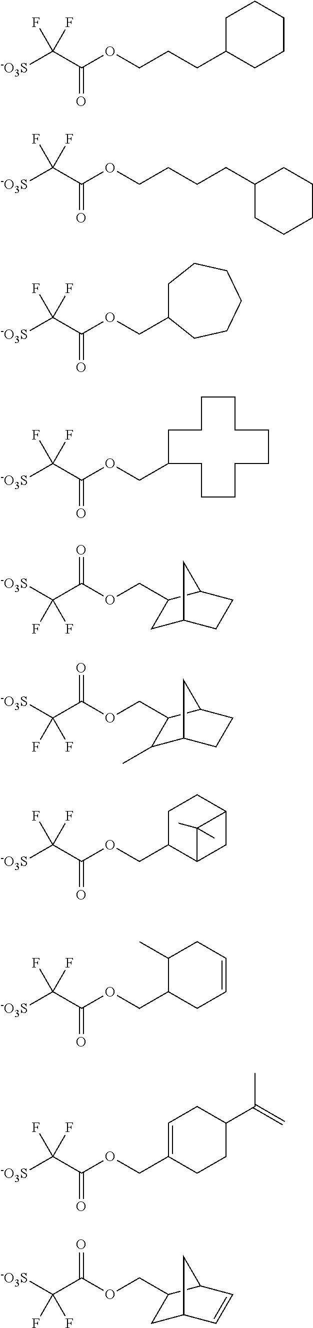

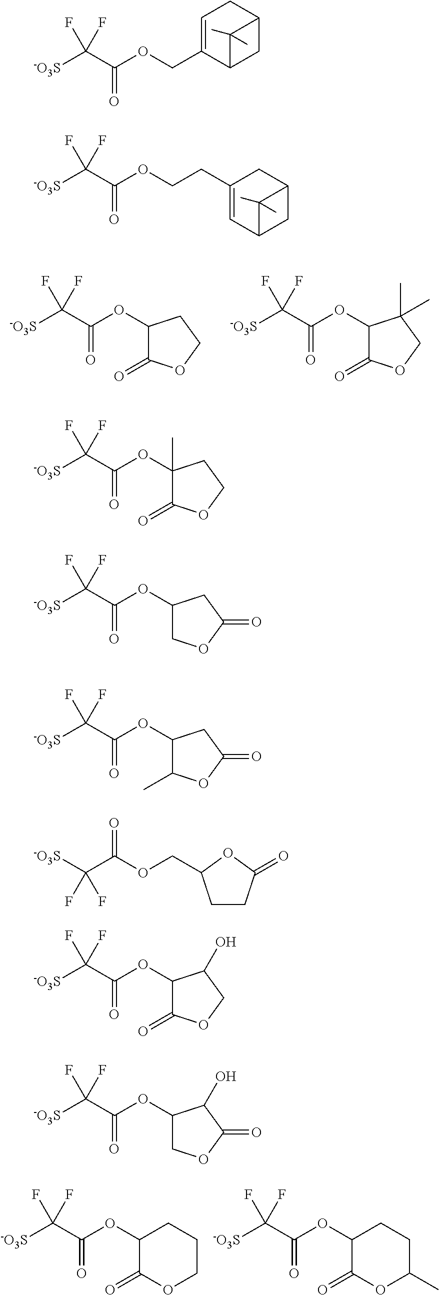

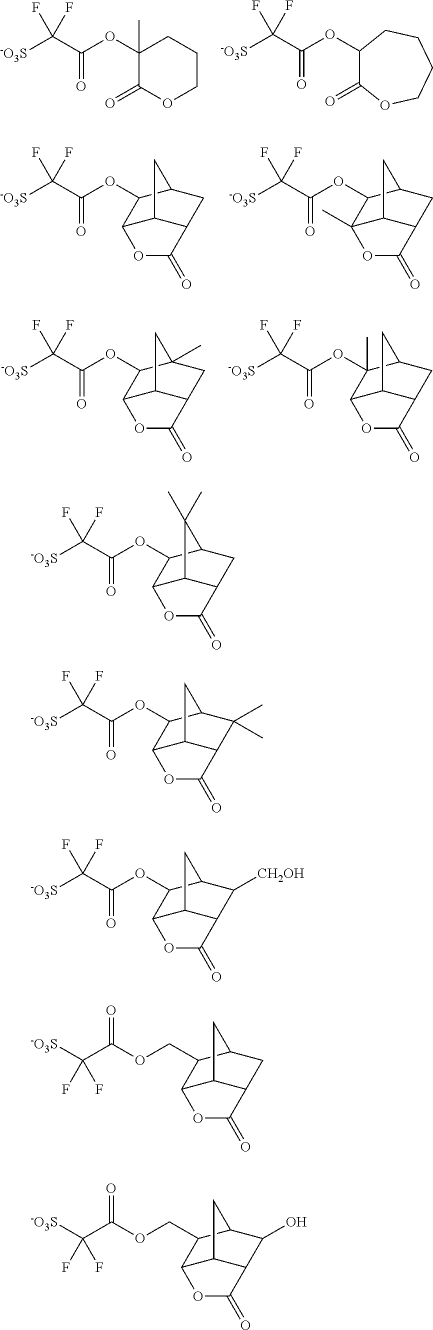

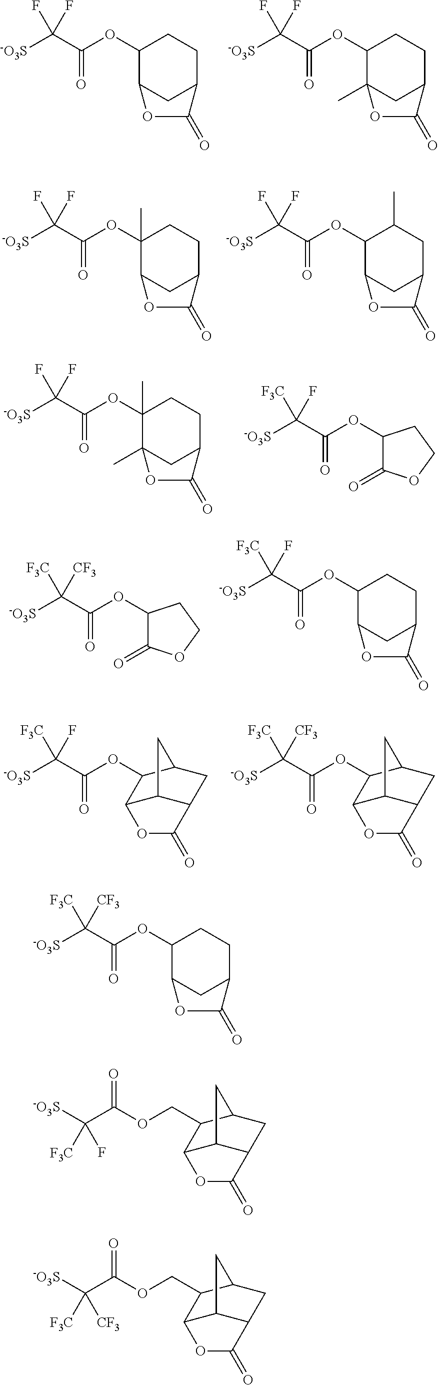

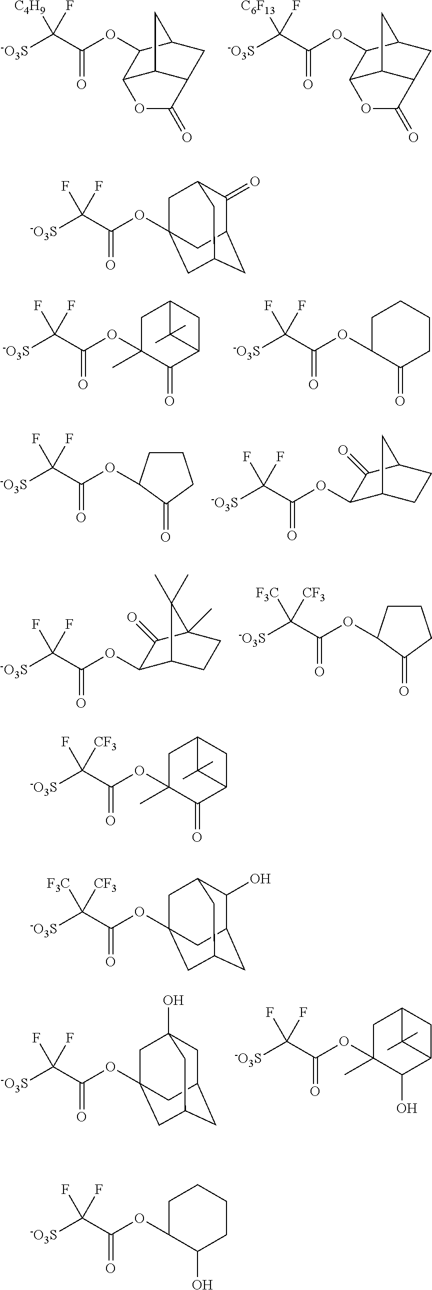

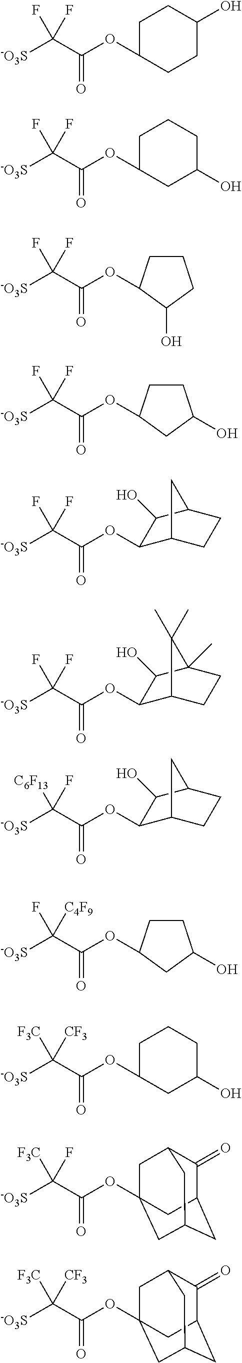

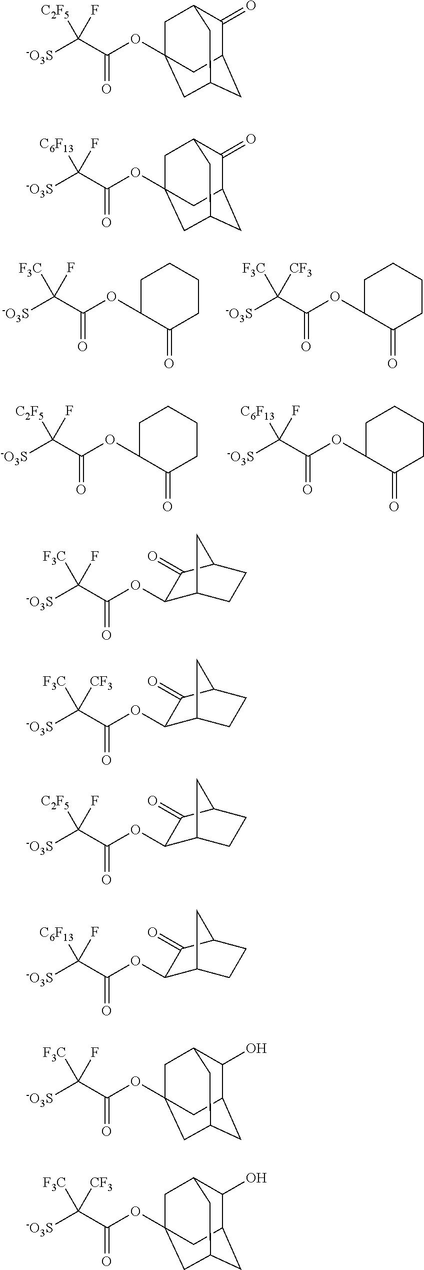

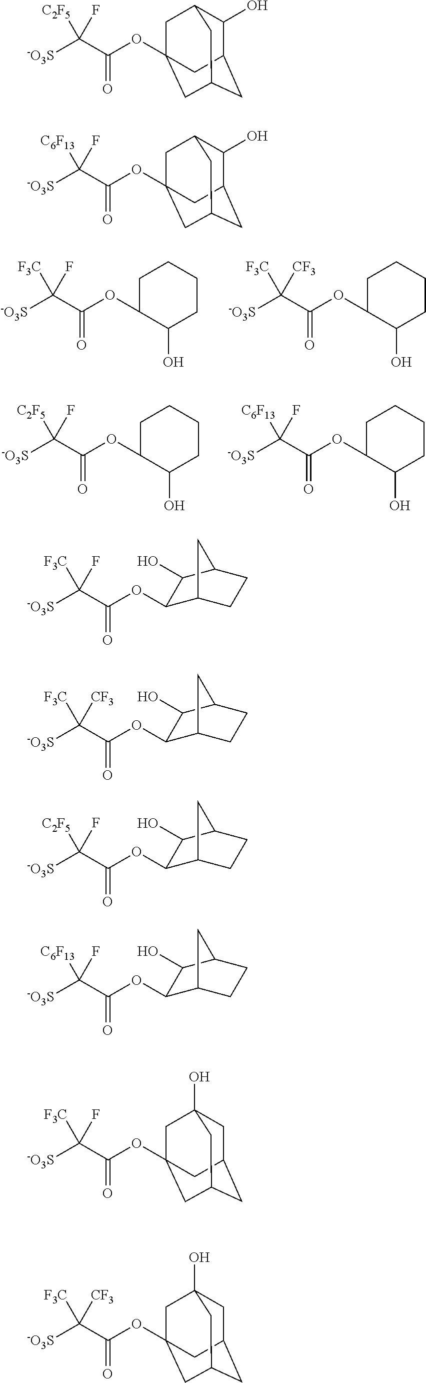

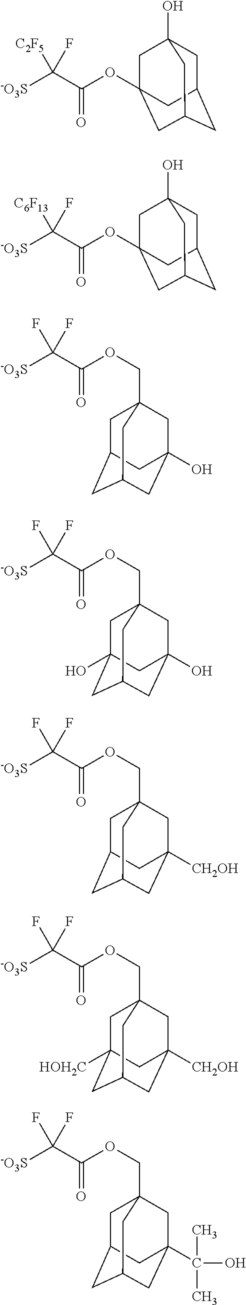

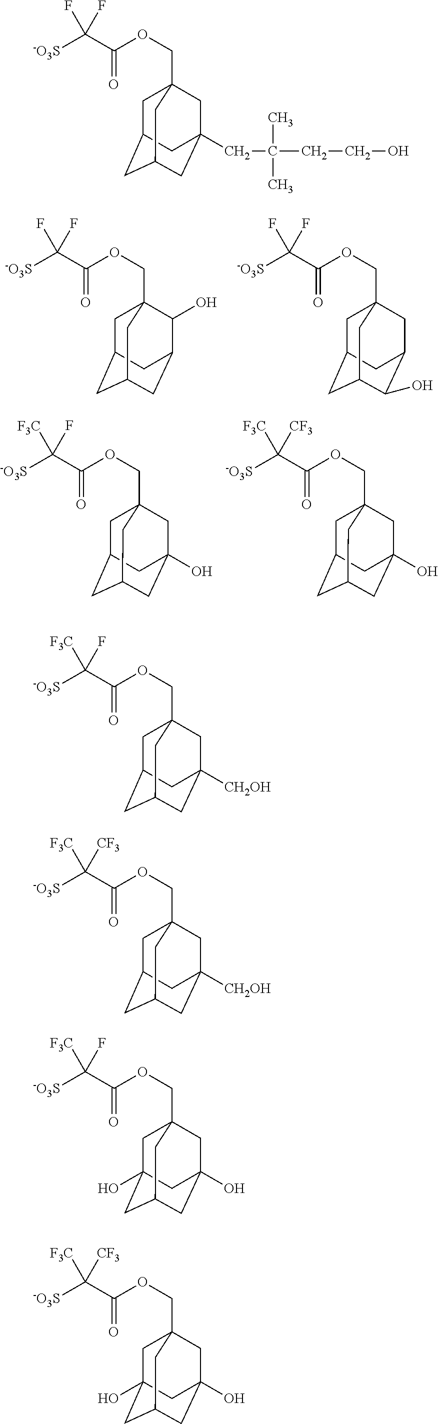

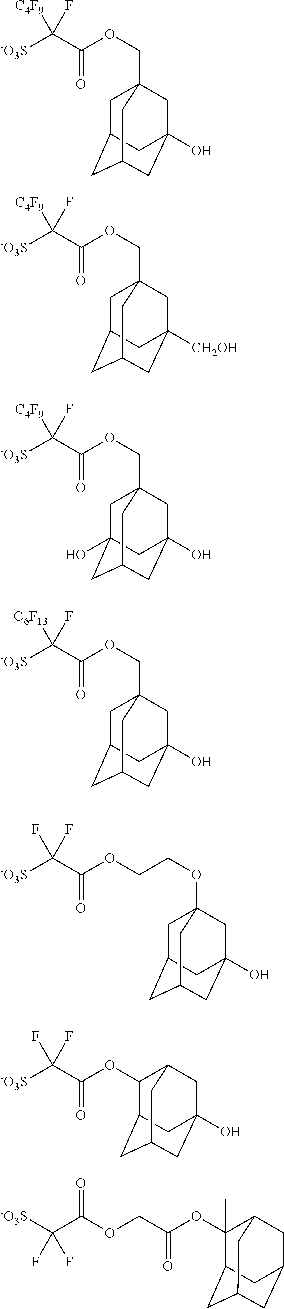

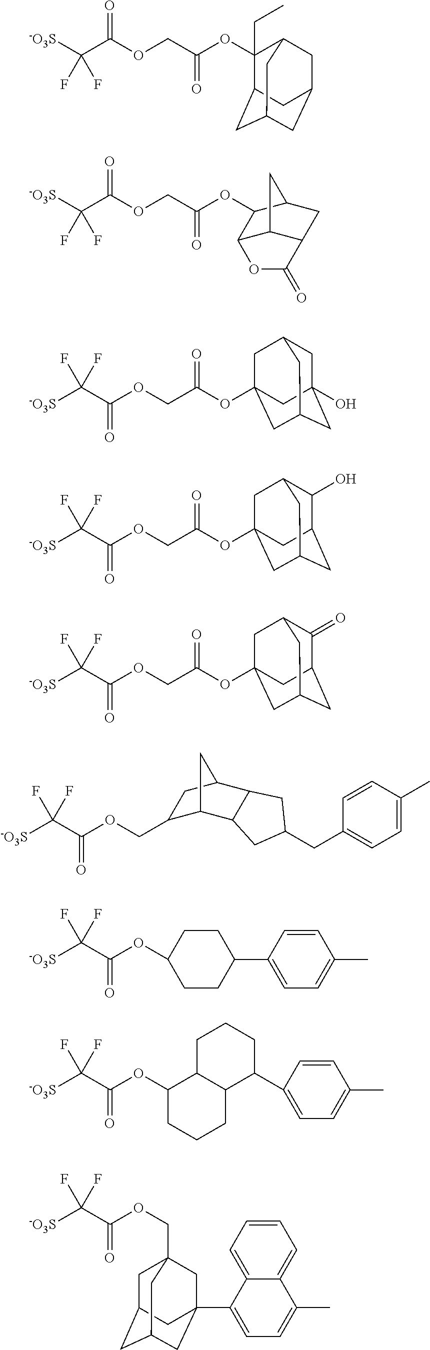

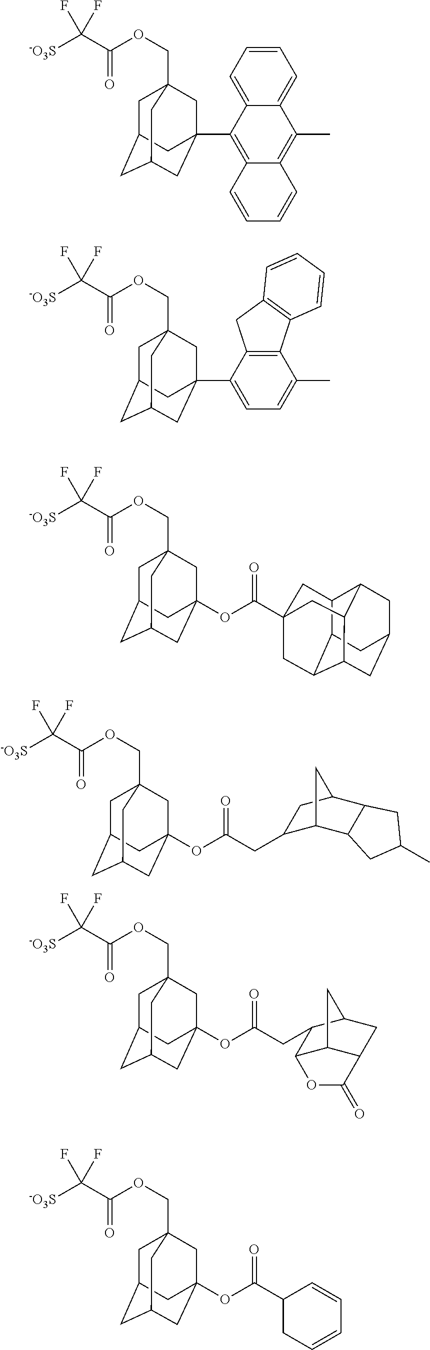

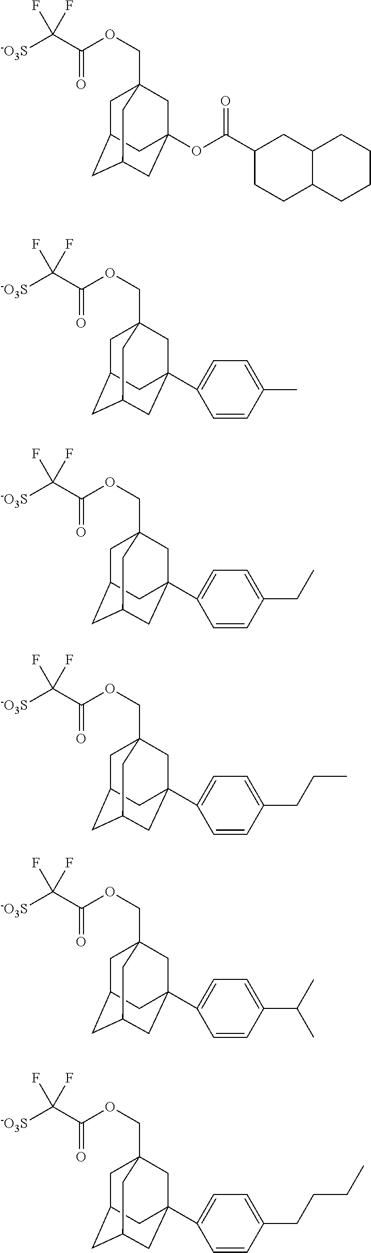

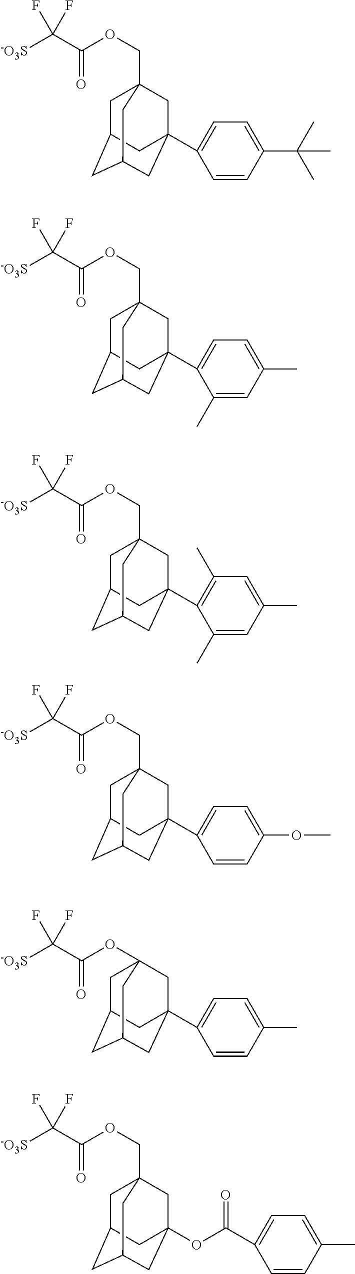

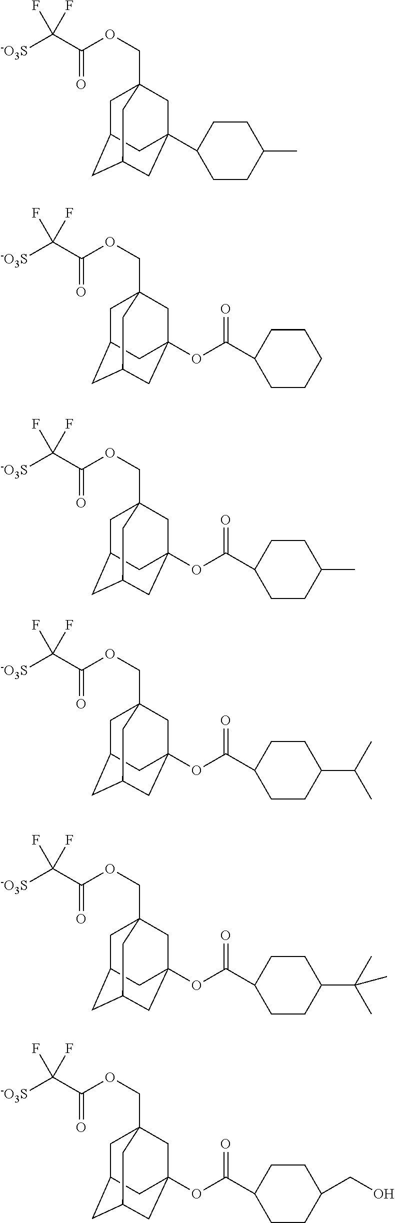

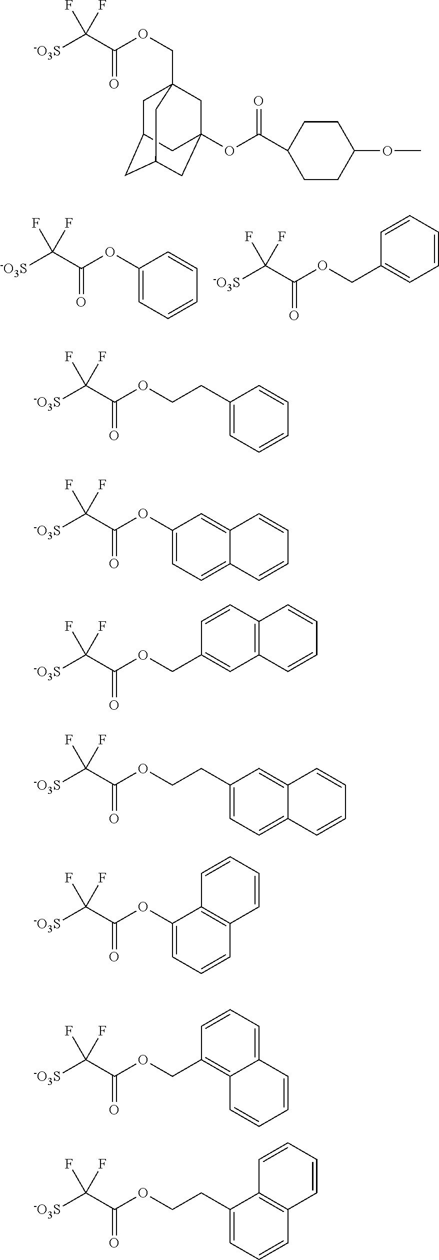

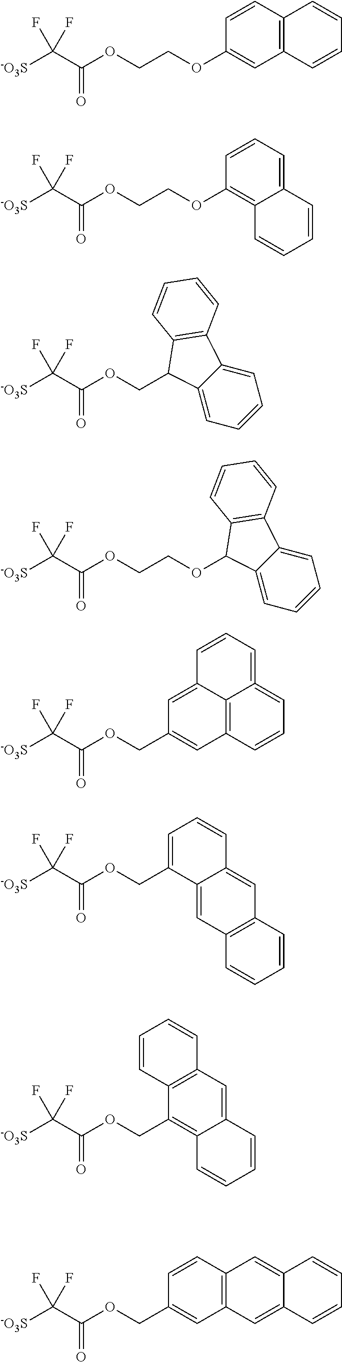

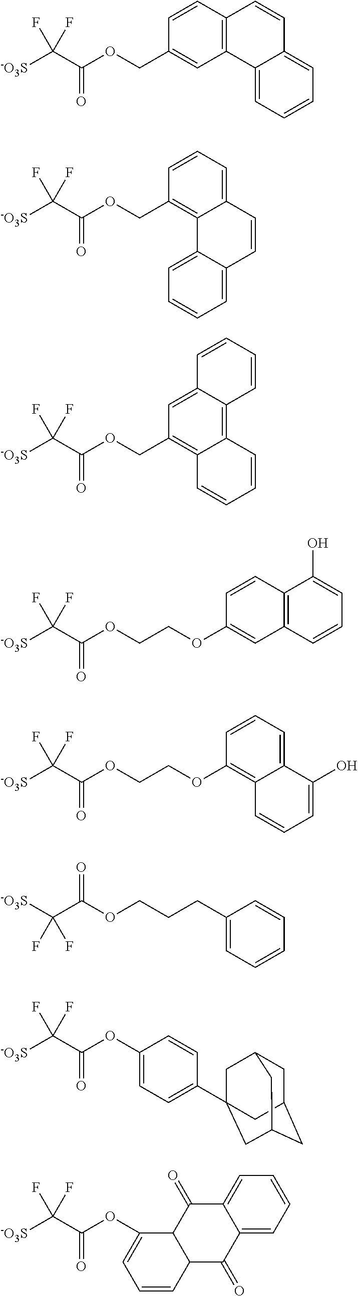

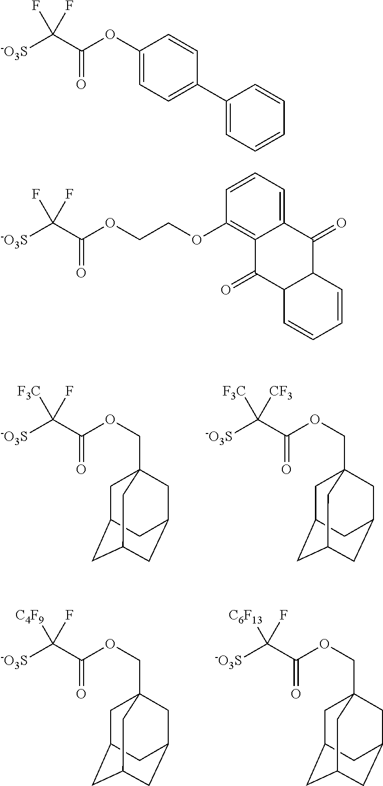

The photo acid generator (B) may be a compound represented by the following formula (VII).

A⁺ ^{-O}₃S—R^{b} (VII)

wherein R^{b} represents a C₁ to C₆ linear or branched chain alkyl group or a perfluoroalkyl group;

A⁺ has the same meaning as defined above.

R^{b} is preferably a C₁ to C₆ perfluoroalkyl group.

Specific examples of the anion of the formula (VII) include an ion such as trifluoromethanesulfonate, pentafluoroethanesulfonate, heptafluoropropansulfonate and perfluorobutanesulfonate.

Examples of the organic counter ion of A⁺ in the compounds represented by the formula (I), (III), (V) to (VII) include a cation represented by the formula (VIII).

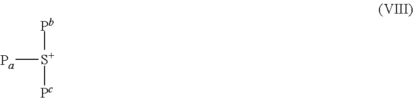

wherein P^{a} to P^{c} independently represent a C₁ to C₃₀ linear or branched chain alkyl group or a C₃ to C₃₀ cyclic hydrocarbon group; when P^{a} to P^{c} are alkyl groups, the groups may be substituted with at least one selected from the group consisting of a hydroxyl group, a C₁ to C₁₂ alkoxy group, a C₃ to C₁₂ cyclic hydrocarbon group, an ether group, an ester group, a carbonyl group, a cyano group, an amino group, an amino group substituted with a C₁ to C₄ alkyl group and an amide group, when P^{a} to P^{c} are cyclic hydrocarbon groups, the groups may be substituted with at least one selected from the group consisting of a hydroxyl group, a C₁ to C₁₂ alkyl group, a C₁ to C₁₂ alkoxy group, an ether group, an ester group, a carbonyl group, a cyano group, an amino group, an amino group substituted with a C₁ to C₄ alkyl group and an amide group.

In particular, examples thereof include the following cations represented by the formula (IIa), the formula (IIb), the formula (IIc) and the formula (IId).

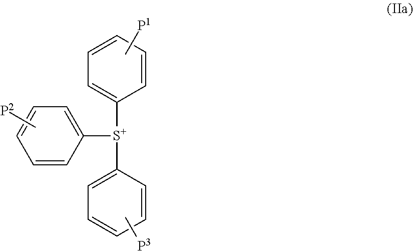

wherein P¹ to P³ independently represent a hydrogen atom, a hydroxyl group, a C₁ to C₁₂ alkyl group, a C₁ to C₁₂ alkoxy group, an ether group, an ester group, a carbonyl group, a cyano group, an amino group optionally substituted with a C₁ to C₄ alkyl group and an amide group,

The alkyl group and the alkoxy group include the same examples as the above.

Among cations represented by the formula (IIa), a cation represented by the formula (IIe) is preferable due to its ease of production.

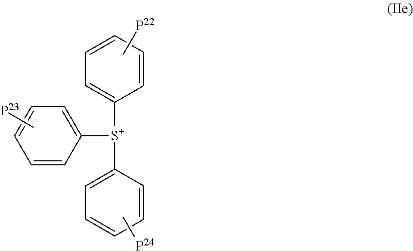

wherein P²² to P²⁴ independently represent a hydrogen atom or a C₁ to C₄ alkyl group. The alkyl group may be a linear or branched chain.

Further, examples of the organic counter ion of A⁺ may be a cation represented by the formula (IIb) containing iodine cation.

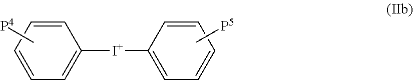

wherein P⁴ and P⁵ independently represent a hydrogen atom, a hydroxyl group, a C₁ to C₁₂ alkyl group or a C₁ to C₁₂ alkoxy group.

Furthermore, examples of the organic counter ion of A⁺ may be a cation represented by the formula (IIc).

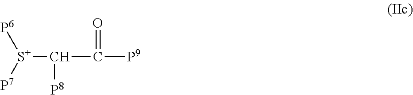

wherein P⁶ and P⁷ independently represent a C₁ to C₁₂ alkyl group or a C₃ to C₁₂ cycloalkyl group. The alkyl group may be a linear or branched chain.

Examples of the cycloalkyl group include cyclopropyl group, cyclobutyl group, cyclopentyl group, cyclohexyl group, cycloheptyl group and cyclodecyl group.

Also, P⁶ and P⁷ may be bonded together to form a C₃ to C₁₂ divalent hydrocarbon group. A carbon atom containing in the divalent hydrocarbon group can be replaced by a carbonyl group, an oxygen atom or a sulfur atom.

The divalent hydrocarbon group may be any of a saturated, unsaturated, chained or cyclic hydrocarbon. Among these, chained saturated hydrocarbon groups, and in particular, alkylene groups are preferred. Example of the alkylene group includes trimethylene, tetramethylene, pentamethylene and hexamethylene.

P⁸ represents a hydrogen atom, P⁹ represents a C₁ to C₁₂ alkyl group, a C₃ to C₁₂ cycloalkyl group or an optionally substituted aromatic group, or P⁸ and P⁹ may be bonded together to form a C₃ to C₁₂ divalent hydrocarbon group.

The alkyl group, the cycloalkyl group and the divalent hydrocarbon group include the same examples as the above.

The aromatic group preferably has 6 to 20 carbon atoms, and for example, is preferably an aryl group or an aralkyl group, and more specifically, includes phenyl, tolyl, xylyl, biphenyl, naphthyl, benzyl, phenethyl and anthracenyl groups. Among these, phenyl group and benzyl group are preferred. A group which may be substituted in the aromatic group include a hydroxyl group, a C₁ to C₆ alkyl group and a C₁ to C₆ hydroxyalkyl group.

Also, examples of the organic counter ion of A⁺ include a cation represented by the formula (IId).

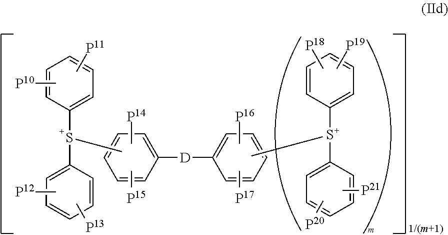

wherein P¹⁰ to P²¹ independently represent a hydrogen atom, a hydroxyl group, a C₁ to C₁₂ alkyl group or a C₁ to C₁₂ alkoxy group.

The alkyl group and the alkoxy group include the same examples as the above.

D represents a sulfur atom or an oxygen atom.

m represents 0 or 1.

Specific examples of the cation A⁺ of the formula (IIa) include cations represented by the following formulae.

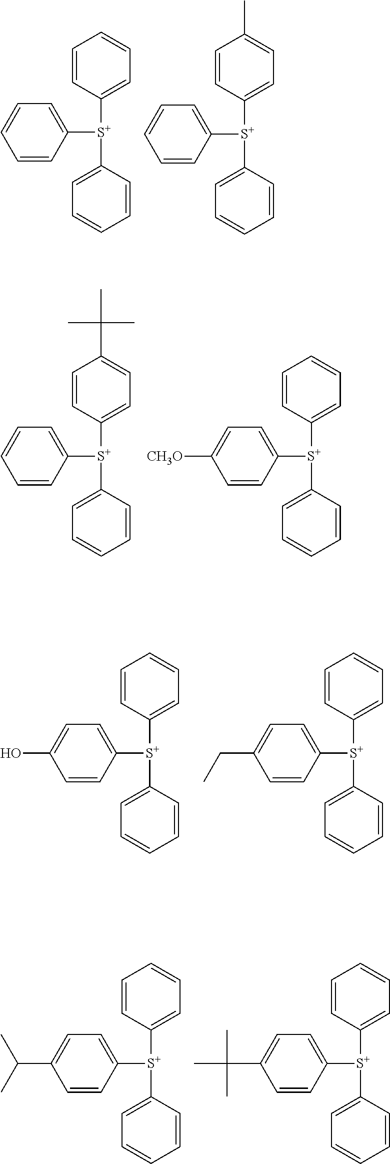

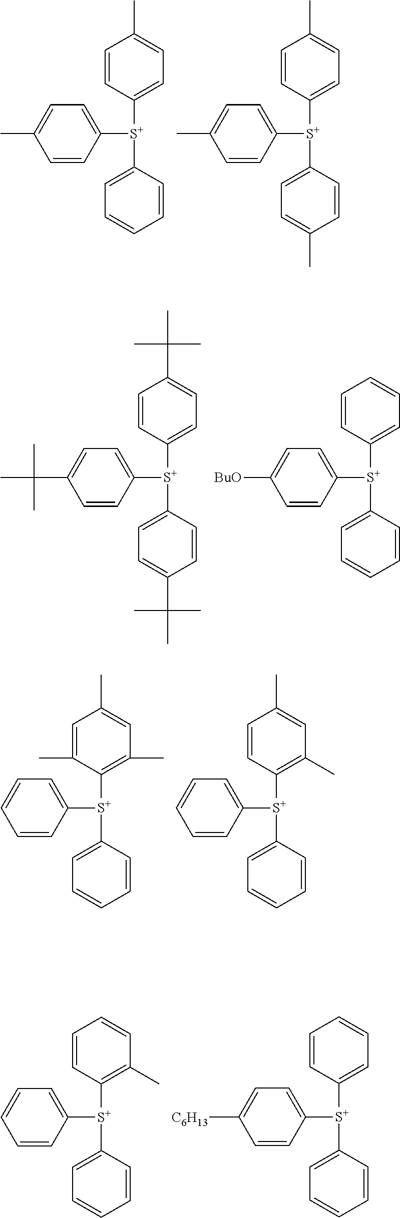

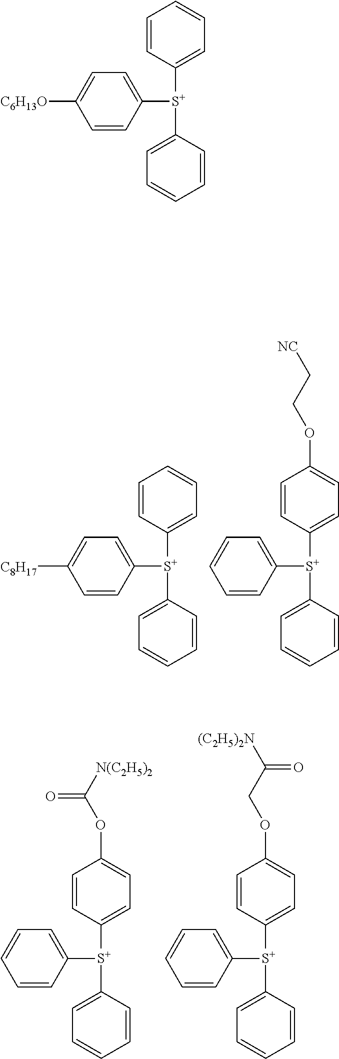

Specific examples of the cation A⁺ of the formula (IIb) include cations represented by the following formulae.

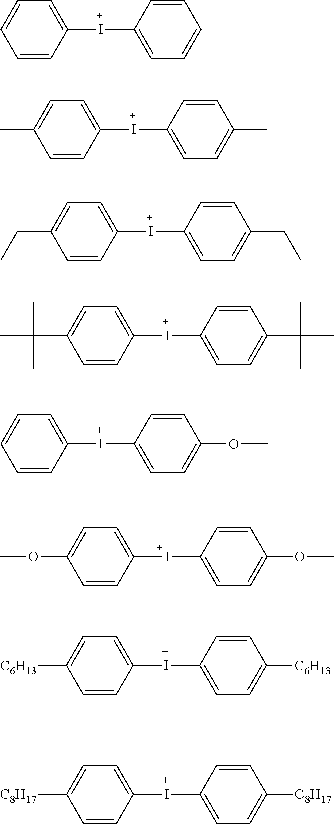

Specific examples of the cation A⁺ of the formula (IIc) include cations represented by the following formulae.

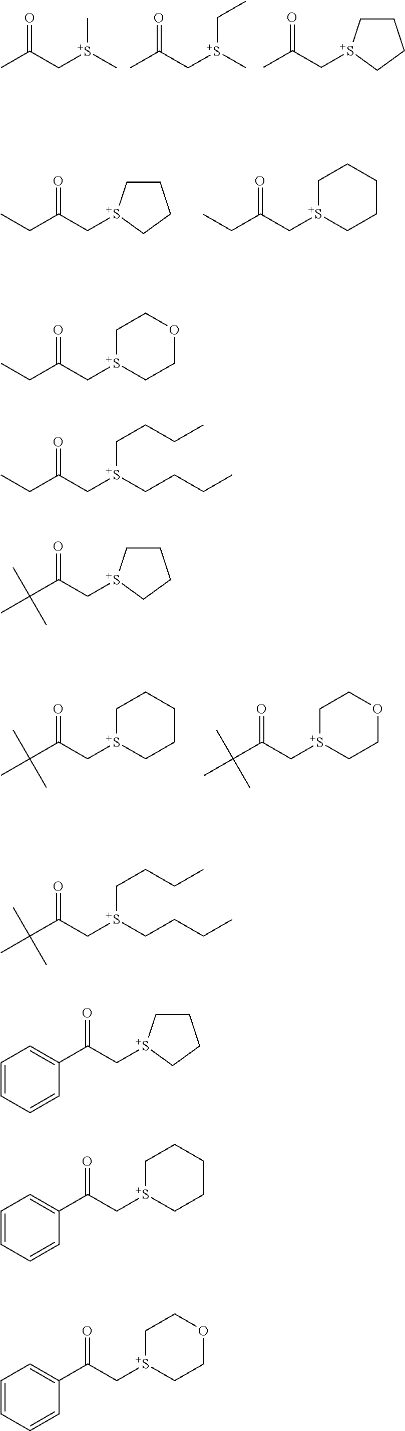

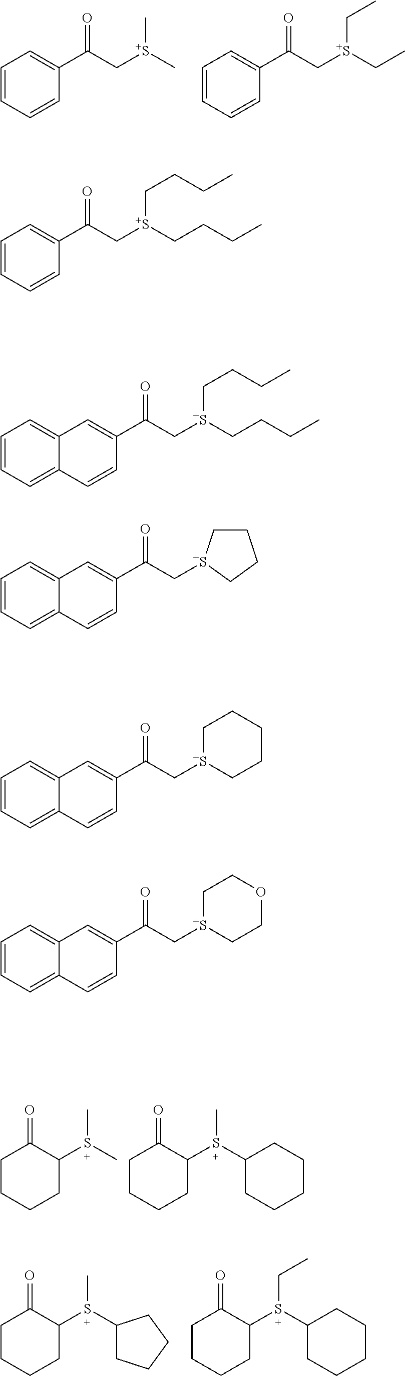

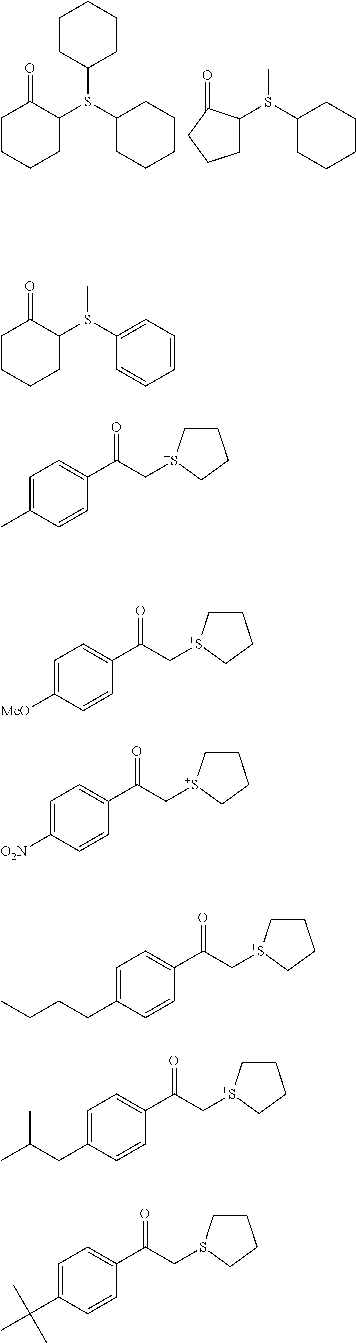

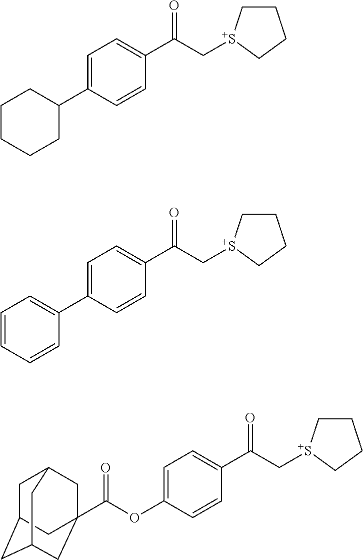

Specific examples of the cation A⁺ of the formula (IId) include cations represented by the following formulae.

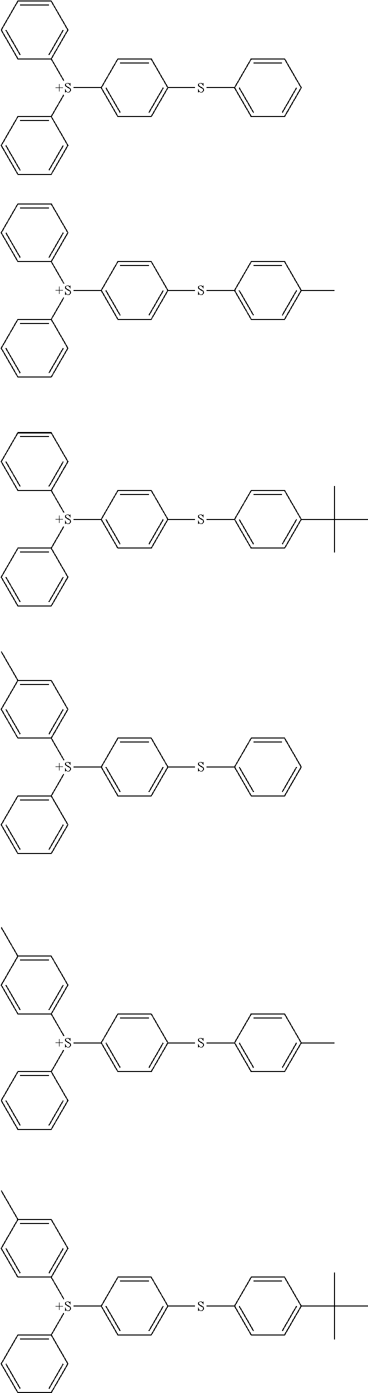

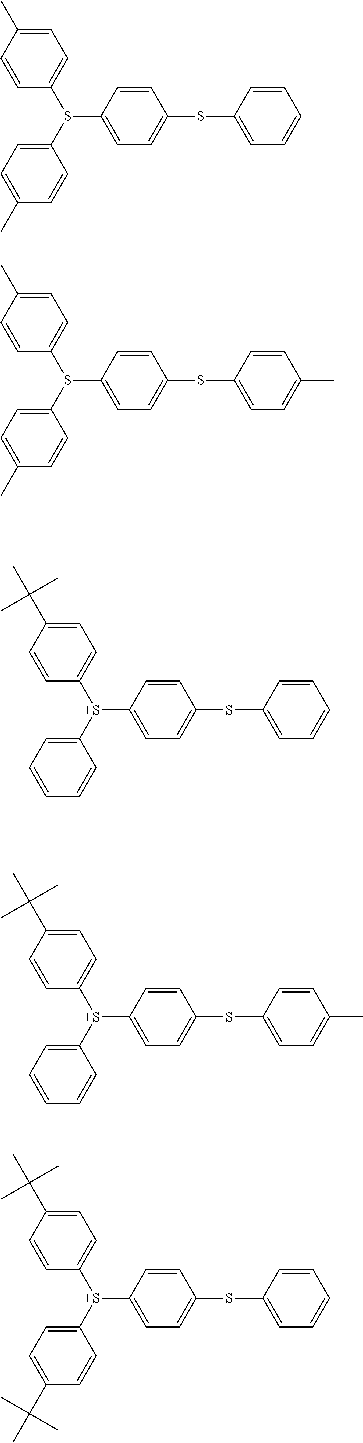

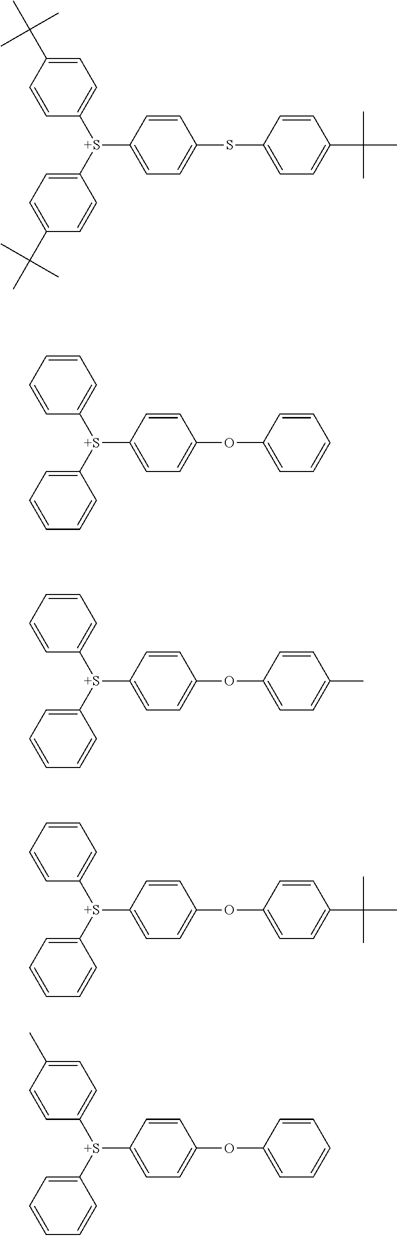

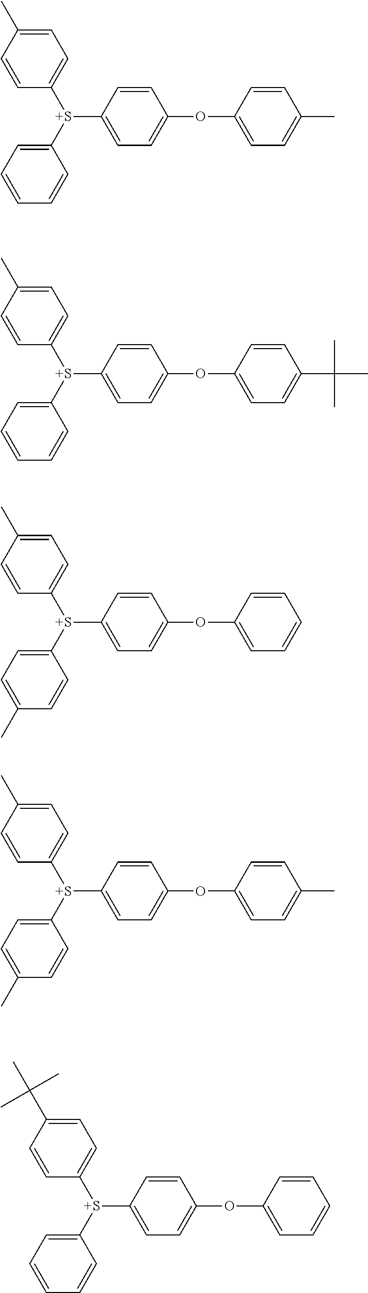

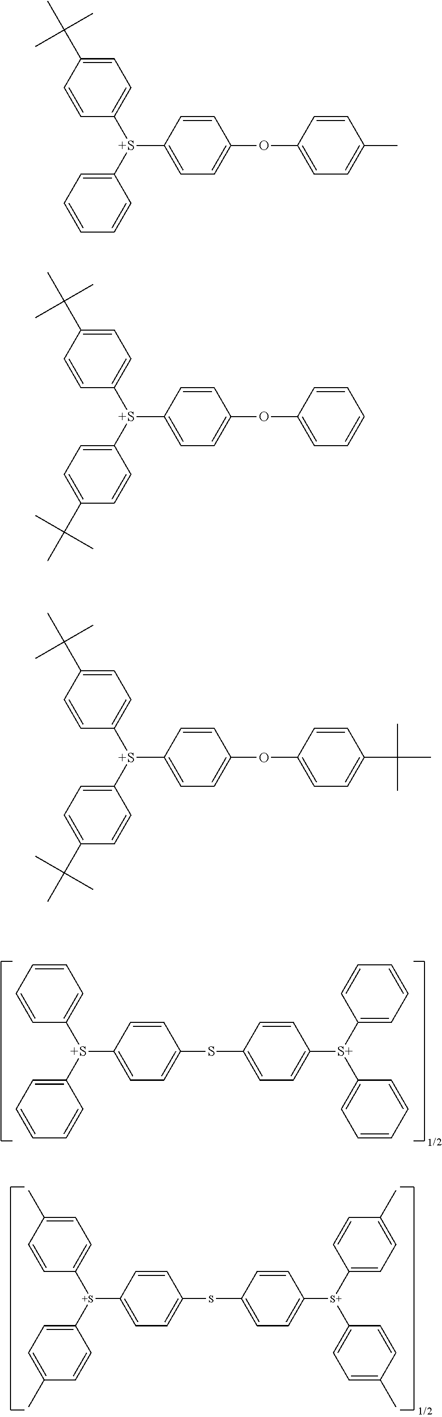

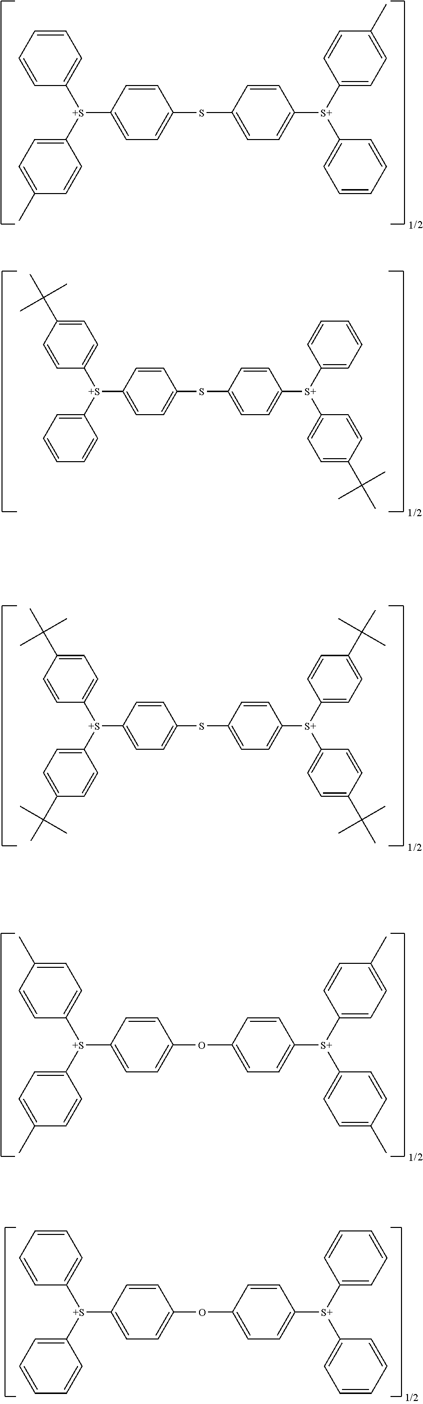

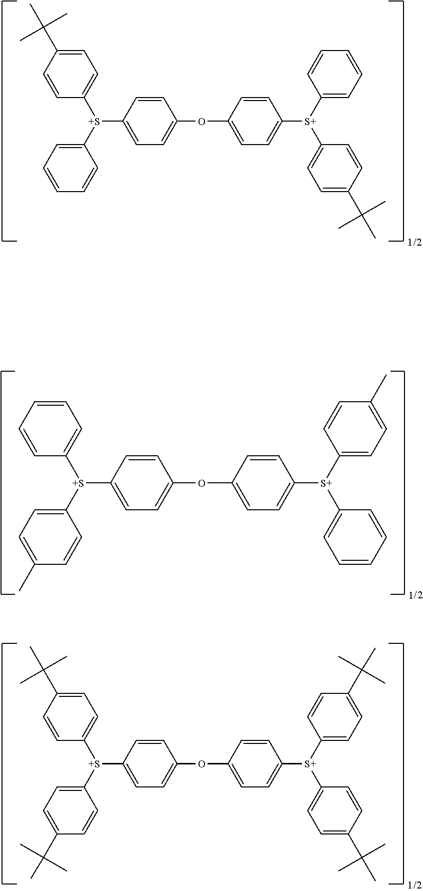

Examples of the cation A⁺ of the compound represented by the formula (I), (III), (V) to (VII) may be a cation represented by the formula (IV).

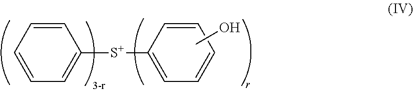

wherein r represents an integer of 1 to 3.

In the formula (IV), r is preferably 1 to 2, and most preferably 2.

There is no particular limitation on the position of bond for a hydroxyl group, but it is preferably at 4-position due to their ease of availability and low cost.

Specific examples of the cation of the formula (IV) include cation represented by the following formulae.

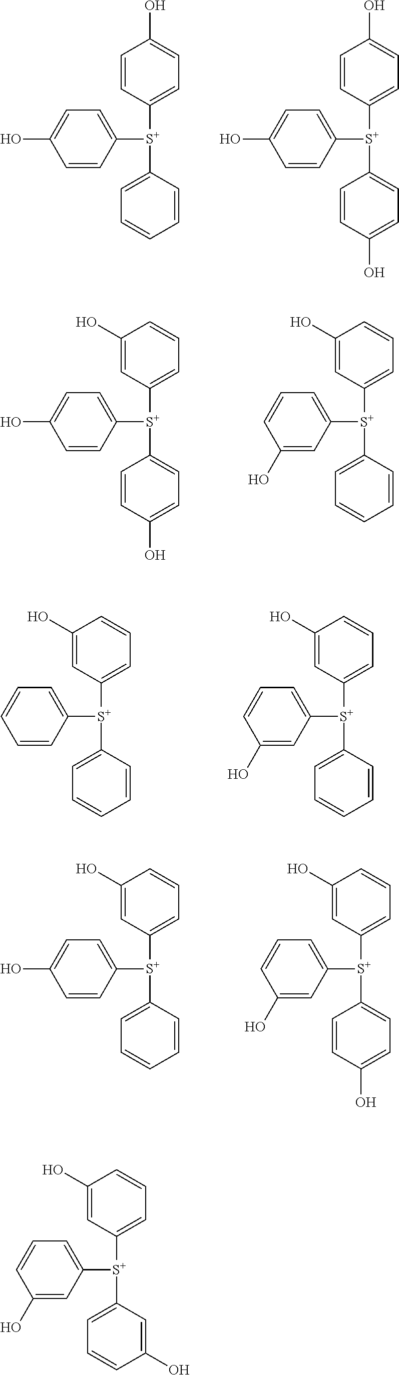

In particular, compounds represented by the formulae (IXa) to (IXe) are preferred as the compound represented by the formula (I) or (III) of the present invention since they form a photo acid generator giving a chemically-amplified resist having an excellent pattern shape and resolution.

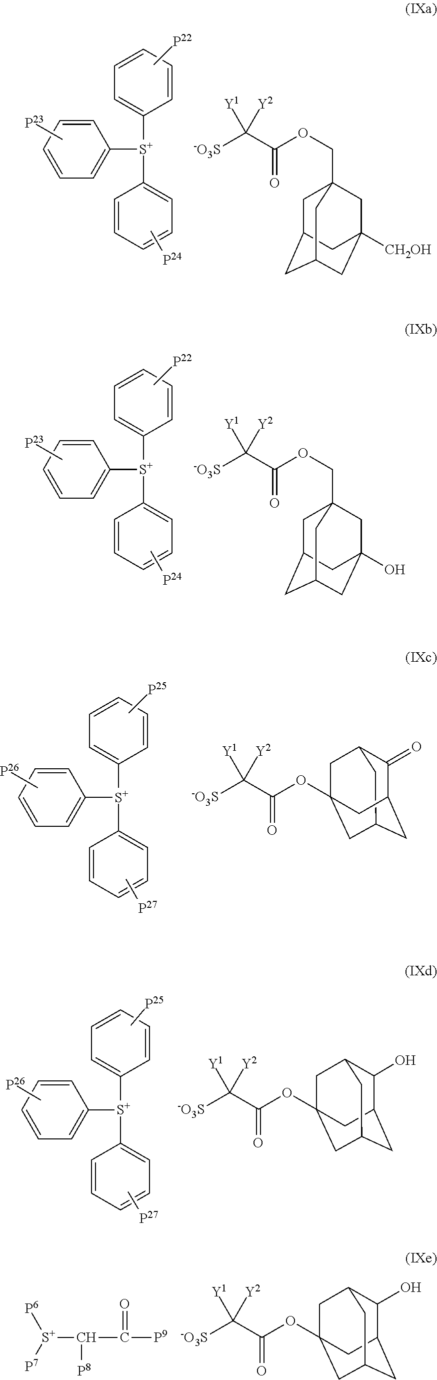

wherein, P⁶ to P⁹ and P²² to P²⁴, Y¹, Y² have the same meaning as defined above, and P²⁵ to P²⁷ independently represent a hydrogen atom or a C₁ to C₄ alkyl group.

Among these, the compounds below are suitably used due to their ease of production.

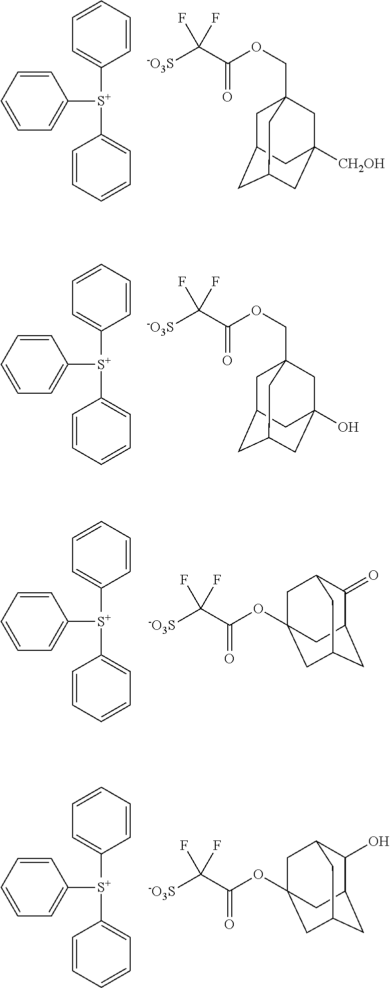

The compounds of the formulae (I), (III), (V) to (VII) can be produced, for example, using a method disclosed in JP-2006-257078-A or an according method.

In particular, the manufacturing method of the compound represented by the formula (V) or the formula (VI) includes a method by reacting a salt represented by the formula (1) or the formula (2) with an onium salt represented by the formula (3) being stirred in an inert solvent such as acetonitrile, water or methanol at a temperature in the range of about 0° C. to 150° C., and preferably 0° C. to 100° C.

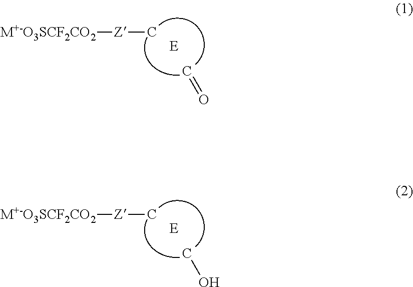

wherein Z′ and E have the same meaning as defined above, and

M represents Li, Na, K or Ag.

A⁺Z⁻ (3)

wherein A⁺ has the same meaning as defined above, and

Z represents F, Cl, Br, I, BF₄, AsF₆, SbF₆, PF₆ or ClO₄.

The onium salt of the formula (3) is generally used in an amount of about 0.5 to 2 mol per 1 mol of the salt represented by the formula (1) or the formula (2). The compound represented by the formula (V) or the formula (VI) may be purified by recrystallization or washing with water.

The salt represented by the formula (1) or the formula (2) that is used to produce the compound represented by the formula (V) or the formula (VI) can be produced, for example, by first esterification-reacting between an alcohol represented by the formula (4) or the formula (5) with a carboxylic acid represented by the formula (6).

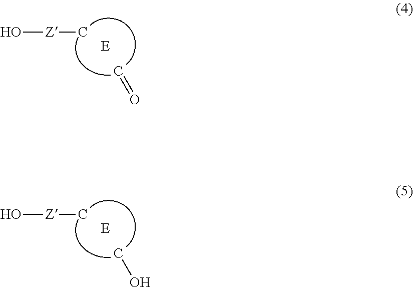

wherein E and Z′ have the same meaning as defined above.

M⁺ ⁻O₃SCF2COOH (6)

wherein M has the same meaning as defined above.

Alternatively, the salt represented by the formula (1) or the formula (2) can be also produced, for example, by first esterification-reacting between an alcohol represented by the formula (4) or the formula (5) with a carboxylic acid represented by the formula (7), and then hydrolyzing with MOH wherein M has the same meaning as defined above.

FO₂SCF₂COOH (7)

The esterification reaction may usually be carried out by stirring in an aprotic solvent such as dichloroethane, toluene, ethyl benzene, monochlorobenzene and acetonitrile at a temperature in the range of about 20° C. to 200° C., and preferably about 50° C. to 150° C. An organic acid such as p-toluenesulfonic acid and/or an inorganic acid such as sulfuric acid is usually added as an acid catalyst during the esterification reaction.

The esterification reaction is also preferably carried out along with dehydration using a Dean-Stark device, etc., because the reaction time tends to be shorter.

The carboxylic acid represented by the formula (6) in the esterification reaction is generally used in an amount of about 0.2 to 3 mol, and preferably about 0.5 to 2 mol, per 1 mol of the alcohol represented by the formula (4) or the formula (5). The amount of the acid catalyst in the esterification reaction may be a catalytic amount or an amount corresponding to the solvent, and is usually about 0.001 to 5 mol.

There are also methods for obtaining salts represented by the formula (VI) or the formula (2) by reducing the salt represented by the formula (V) or the formula (1).

The reducing reaction can be brought about using a reducing agent, including borohydrides such as sodium borohydride, zinc borohydride, lithium tri-sec-butyl borohydride and borane; aluminum hydrides such as lithium tri-t-butoxyaluminum hydride and diisobutylaluminum hydride; organosilicon hydrides such as Et₃SiH and Ph₂SiH₂; or organotin hydrides such as Bu₂SnH, in a solvent such as water, alcohol, acetonitrile, N,N-dimethyl formamide, diglyme, tetrahydrofuran, diethyl ether, dichloromethane, 1,2-dimethoxyethane, or benzene. The reaction may be brought about while stirred at a temperature in the range from about −80° C. to 100° C., and preferably about −10° C. to 60° C.

Photo acid generators shown in (B1) and (B2) below may be used as the photo acid generator (B).

(B1) is not particularly limited as long as at least one hydroxyl group is present in the cation and an acid is produced by exposure. Such cations include those represented by formula (IV) above.

The anion in (B1) is not particularly limited and for example known anions of an onium salt type acid generator may be suitably used.

For example, an anion represented by the formula (X-1), formula (X-2), (X-3) or (X-4).

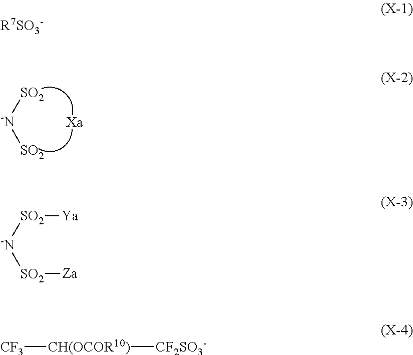

wherein R⁷ is a linear or branched chain, or cyclic alkyl group or a fluoroalkyl group;

Xa represents a C₂ to C₆ alkylene group in which at least one hydrogen atom is substituted by a fluorine atom;

Ya and Za independently represent a C₁ to C₁₀ alkyl group in which at least one hydrogen atom is substituted by a fluorine atom;

R¹⁰ is a substituted or non-substituted linear or branched chain, or cyclic C₁ to C₂₀ alkyl group, or a substituted or non-substituted C₆ to C₁₄ aryl group.

The linear or branched chain alkyl group preferably has 1 to 10 carbon atoms, more preferably 1 to 8 carbon atoms, and most preferably 1 to 4 carbon atoms.

The cyclic alkyl group, R⁷ preferably has 4 to 15 carbon atoms, more preferably 4 to 12 carbon atoms, and still more preferably 4 to 10, 5 to 10, and 6 to 10 carbon atoms.

The fluoroalkyl group preferably has 1 to 10 carbon atoms, more preferably 1 to 8 carbon atoms, and most preferably 1 to 4 carbon atoms.

The rate of fluorination of the fluoroalkyl group (the proportion of the number of fluorine atoms substituted by fluorination relative to the total number of hydrogen atoms in the alkyl group prior to fluorination, same hereafter) is preferably 10 to 100%, and more preferably 50 to 100% and, in particular, all hydrogen atoms substituted by fluorine atoms is preferred since the strength of the acid is increased.

R⁷ is more preferably a linear chain or cyclic alkyl group, or a fluorinated alkyl group.

In the formula (X-2), Xa represents a linear or branched chain alkylene group in which at least one hydrogen atom is substituted by a fluorine atom. The number of carbon atoms in the alkylene group is preferably 2 to 6, more preferably 3 to 5 carbon atoms, and most preferably 3 carbon atoms.

In the formula (X-3), Ya, Za independently represent a linear or branched chain alkyl group in which at least one hydrogen atom is substituted by a fluorine atom. The number of carbon atoms in the alkyl group is preferably 1 to 10, more preferably 1 to 7 carbon atoms, and most preferably 1 to 3 carbon atoms.

The number of carbon atoms in the alkylene group Xa or the alkyl group Ya, Za is preferably as small as possible within the above scope of the carbon atoms due reasons such as a preferred effect on the solubility in the resist solvent and the like.

The strength of the acid is increased as the number of hydrogen atoms substituted by fluorine atoms increases in the alkylene group Xa or the alkyl group Ya, Za, and is preferred due to an improvement in transparency to high-energy light or an electron beam of 200 nm or less. The fluorination rate of the alkylene group or the alkyl group is preferably 70 to 100%, more preferably 90 to 100% and most preferably is a perfluoroalkylene group or a perfluoroalkyl group in which all hydrogen atoms are substituted by fluorine atoms.

Examples of the aryl group include phenyl, tolyl, xylyl, cumenyl, mesityl, naphthyl, biphenyl, anthryl and phenanthryl.

Examples of the substituent which may be substituted alkyl or aryl group include, for example, one or more substituent such as a hydroxyl group, a C₁ to C₁₂ alkyl group, a C₁ to C₁₂ alkoxy group, an ether group, an ester group, a carbonyl group, a cyano group, an amino group, an amino group substituted with a C₁ to C₄ alkyl group and an amide group.

The anion of (B1) includes the anion represented by A⁺ in formula (I) above.

(B1) is preferably has an anion represented by the formula (X-1) described above, and in particular, one in which R⁷ is a fluorinated alkyl group is preferred.

Specific examples of the formula (B1) include the photo acid generator represented by the following formulae.

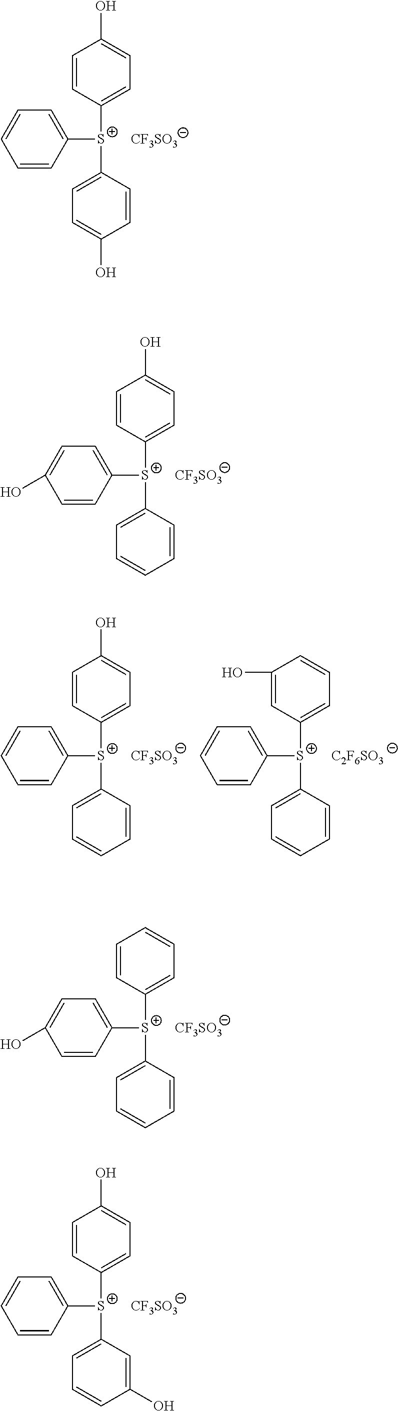

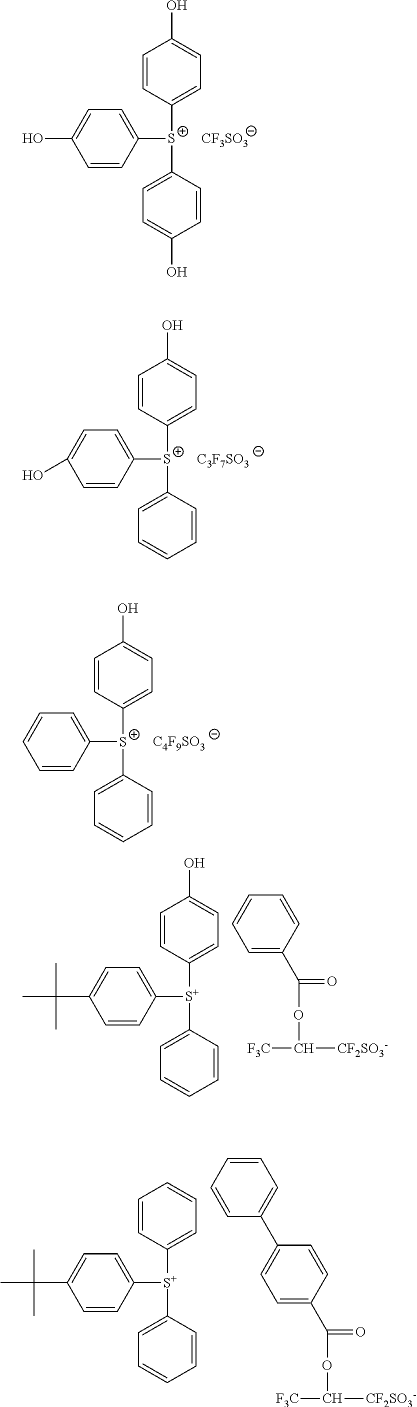

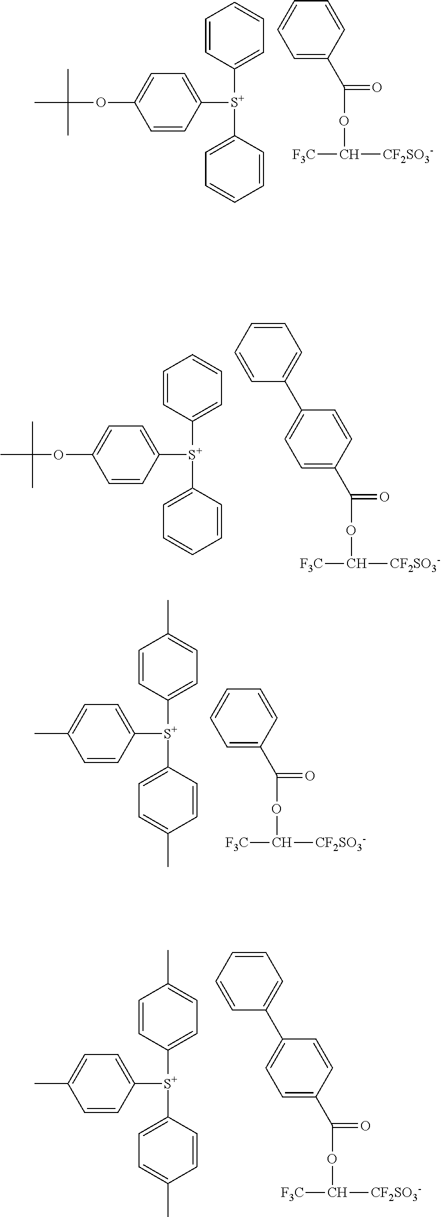

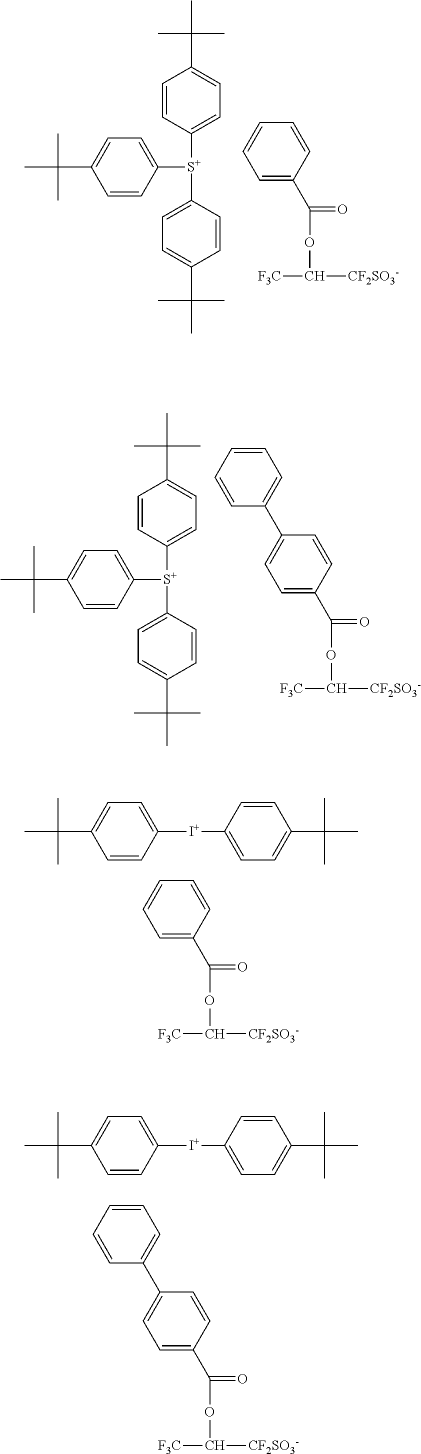

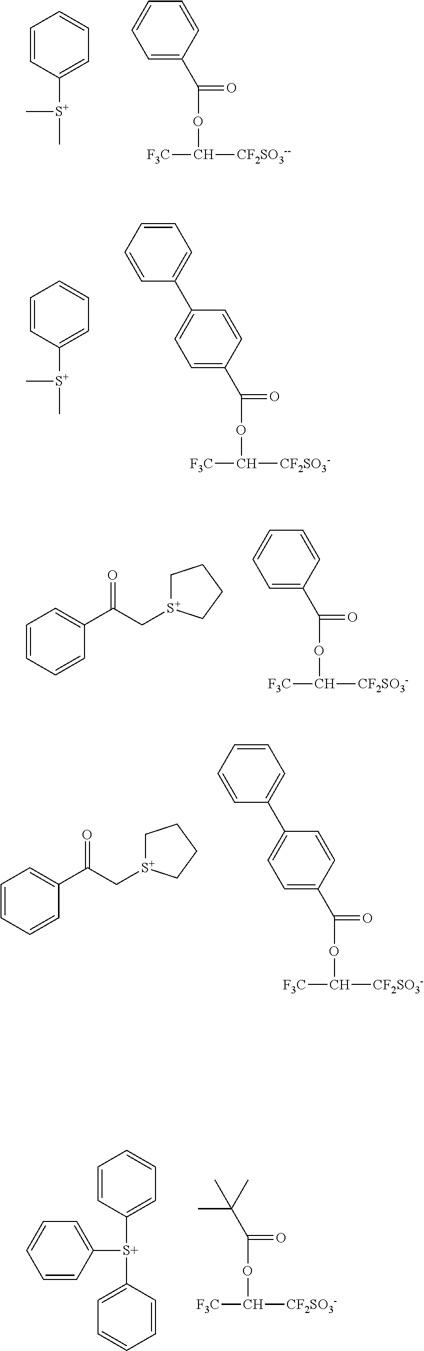

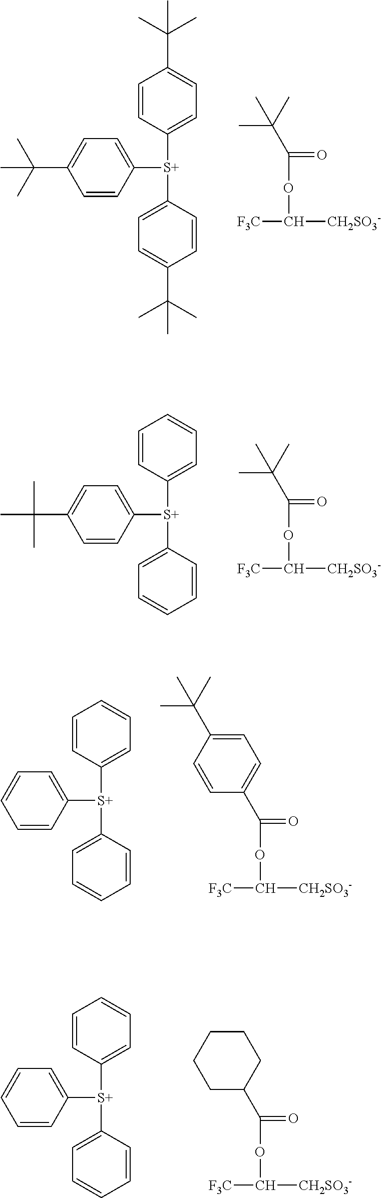

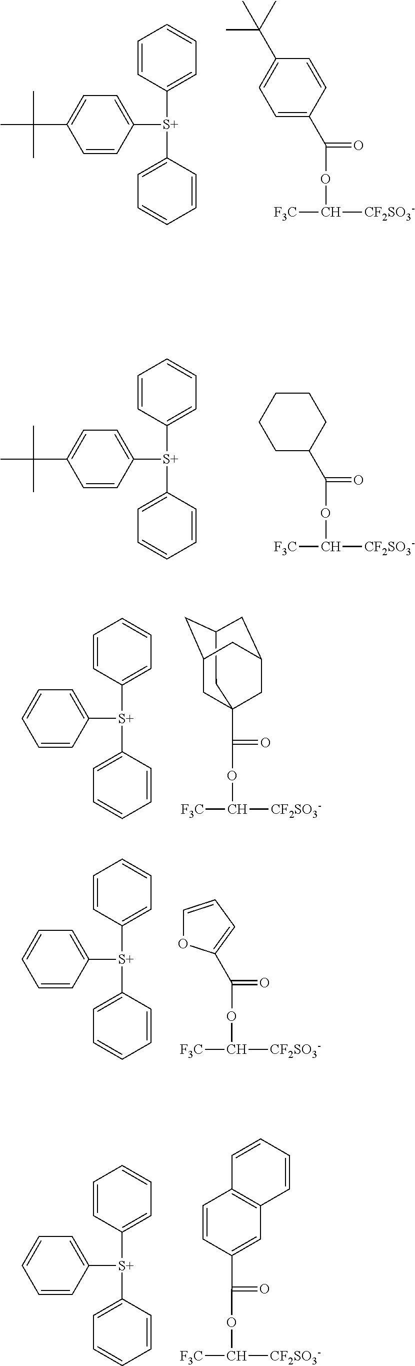

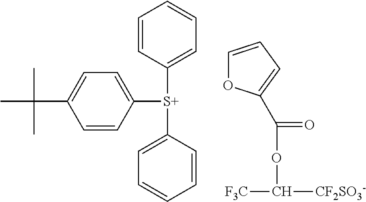

There is no particular limitation on (B2) as long as the cation does not include a hydroxyl group, and any known compound provided for use as an acid generator for a chemically-amplified resist may be used.

This type of acid generator includes an onium salt type acid generator such as an iodonium salt and a sulfonium salt; an oxime sulfonate type acid generator; a diazomethane type acid generator such as bisalkyl or bisaryl sulfonyl diazomethane or poly(bis-sulfonyl)diazomethane; a nitrobenzyl sulfonate acid generator, an iminosulfonate acid generator and a disulfone acid generator.

An onium salt acid generator for example may suitably be an acid generator as represented by the formula (XI).

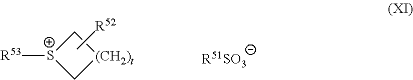

wherein R⁵¹ represents a linear or branched chain, or cyclic alkyl group or a linear or branched chain, or cyclic fluoroalkyl group;

R⁵² represents a hydrogen atom, a hydroxyl group, a halogen atom, a linear or branched chain alkyl group, a linear or branched chain halogenated alkyl group, or a linear or branched chain alkoxy group;

R⁵³ represents an optionally substituted aryl group;

t represents an integer of 1 to 3.

In the formula (XI), R⁵¹ can have the same carbon atom number and fluorination rate as the substituent R⁷ described above.

R⁵¹ is most preferably a linear chain alkyl group or a fluoroalkyl group.

Examples of the halogen atom include fluorine atom, bromine atom, chlorine atom or iodine atom, and fluorine atom is preferred.

In R⁵², the alkyl group is a group in which it is linear or branched chain and preferably has 1 to 5 carbon atoms, and in particular 1 to 4, and more preferably 1 to 3.

In R⁵², the halogenated alkyl group is a group in which a part or all of the hydrogen atoms in the alkyl group are substituted by halogen atoms. The alkyl group and the substituting halogen atoms are the same examples as the above. In the halogenated alkyl group, 50 to 100% of all of the hydrogen atoms are preferably substituted by halogen atoms, and substitution of all atoms is more preferred.

In R⁵², the alkoxy group is a group in which it is linear or branched chain and preferably has 1 to 5 carbon atoms, and in particular 1 to 4, and more preferably 1 to 3.

Among these, R⁵² is preferably a hydrogen atom.

From the point of view of absorption of exposure light such as an ArF excimer laser, R⁵³ is preferably a phenyl group.

Examples of the substituent in the aryl group include a hydroxyl group, a lower alkyl group (linear or branched chain, for example, with 1 to 6 carbon atoms, more preferably 1 to 4 carbon atoms, and in particular a methyl group is preferred), a lower alkoxy group.

The aryl group of R⁵³ more preferably does not include a substituent.

t is an integer of 1 to 3, 2 or 3 are preferred and in particular, 3 is desirable.

Specific examples of the acid generator represented by the formula (XI) include the following compounds.

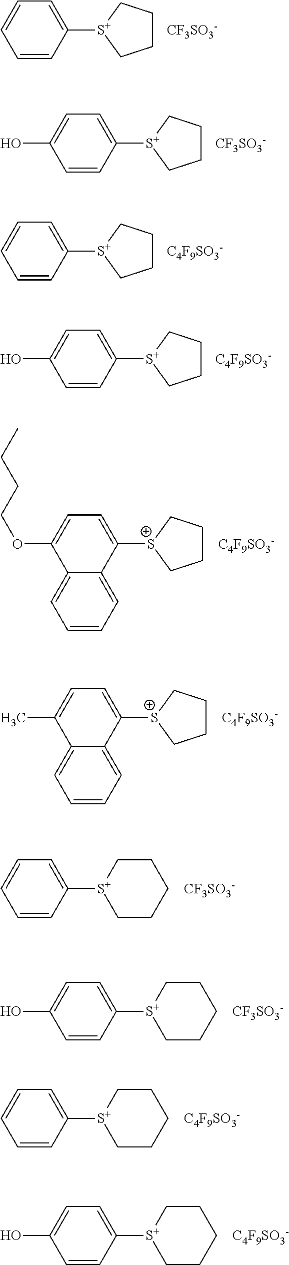

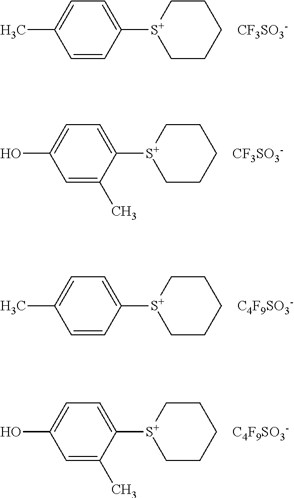

Acid generators represented by the formula (XII) and (XIII) may be used as the onium salt acid generator.

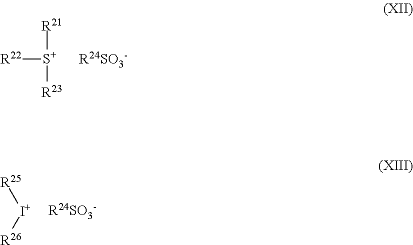

wherein R²¹ to R²³ and R²⁵ to R²⁶ independently represent an aryl group or an alkyl group;

R²⁴ represents a linear or branched chain, or cyclic alkyl group or fluorinated alkyl group;

at least one of R²¹ to R²³ is an aryl group, at least one of R²⁵ to R²⁶ is an aryl group.

Two or more of R²¹ to R²³ are preferably aryl groups, and it is most preferred that all of R²¹ to R²³ are aryl groups.

The aryl group of R²¹ to R²³ is, for example, a C₆ to C₂₀ aryl group. A part or all of the hydrogen atoms in the aryl group may be substituted with an alkyl group, an alkoxy group or a halogen atom. The aryl group is preferably a C₆ to C₁₀ aryl group in view of cost-effective synthesis. Specific examples include a phenyl group and naphtyl group.

The alkyl group which may substitute for the hydrogen atom in the aryl group is preferably a C₁ to C₅ alkyl group, and most preferably methyl group, ethyl group, propyl group, n-butyl group and tert-butyl group.

The alkoxy group which may substitute for the hydrogen atom in the aryl group is preferably a C₁ to C₅ alkoxy group, and most preferably methoxy group or ethoxy group.

The halogen atom which may substitute for the hydrogen atom in the aryl group is preferably a fluorine atom.

The alkyl group in R²¹ to R²³ is, for example, a C₁ to C₁₀ linear or branched chain, or cyclic alkyl group. From the point of view of excellent resolution characteristics, C₁ to C₅ is preferred. Specific examples include methyl group, ethyl group, n-propyl group, iso-propyl group, n-butyl group, isobutyl group, n-pentyl group, cylopentyl group, hexyl group, cyclohexyl group, nonyl group and decanyl group. The methyl group is preferably in view of excellent resolution and cost-effective synthesis.

Among these, R²¹ to R²³ are most preferably a phenyl group or a naphtyl group, respectively.

R²⁴ includes the same groups as mentioned in the above R⁷.

It is preferred that all of R²⁵ to R²⁶ are aryl groups.

Among these, it is most preferred that all of R²⁵ to R²⁶ are phenyl groups.

Example of the onium salt type acid generator represented by the formula (XII) and the formula (XIII) include;

diphenyliodonium trifluoromethanesulfonate or nonafluorobutanesulfonate,

bis(4-tert-butylphenyl)iodonium trifluoromethanesulfonate or nonafluorobutanesulfonate,

triphenylsulfonium trifluoromethanesulfonate, its heptafluoropropanesulfonate or its nonafluorobutanesulfonate,

tri(4-methylphenyl)sulfonium trifluoromethanesulfonate, its heptafluoropropanesulfonate or its nonafluorobutanesulfonate,

dimethyl(4-hydroxynaphtyl)sulfonium trifluoromethanesulfonate, its heptafluoropropanesulfonate or its nonafluorobutanesulfonate,

monophenyldimethylsulfonium trifluoromethanesulfonate, its heptafluoropropanesulfonate or its nonafluorobutanesulfonate,

diphenylmonomethylsulfonium trifluoromethanesulfonate, its heptafluoropropanesulfonate or its nonafluorobutanesulfonate,

(4-methylphenylldiphenylsulfonium trifluoromethanesulfonate, its heptafluoropropanesulfonate or its nonafluorobutanesulfonate,

(4-methoxylphenyl)diphenylsulfonium trifluoromethanesulfonate, its heptafluoropropanesulfonate or its nonafluorobutanesulfonate,

tri(4-tert-butyl)phenylsulfonium trifluoromethanesulfonate, its heptafluoropropanesulfonate or its nonafluorobutanesulfonate,

diphenyl(1-(4-methoxy)naphtyl)sulfonium trifluoromethanesulfonate, its heptafluoropropanesulfonate or its nonafluorobutanesulfonate,

di(1-naphtyl)phenylsulfonium trifluoromethanesulfonate, its heptafluoropropanesulfonate or its nonafluorobutanesulfonate,

1-(4-n-butoxynaphtyl)tetrahydrothiophenium perfulorooctanesulfonate, its 2-bicyclo[2.2.1]hept-2-yl -1,1,2,2-tetrafuluoroethanesulfonate, and

N-nonafluorobutansulfonyloxybicyclo[2.2.1]hept-5-ene-2,3-dicarboxyimide.

An onium salt in which an anion in the onium salt is replaced by methansulfonate, n-propanesurfonate, n-butanesulfonate, n-octanesulfonate may be used.

In the formula (XII) or (XIII), an onium salt type acid generator in which anion is replaced by an anion represented by the formulae (X-1) to (X-3) may be used.

The following compounds may be also used.

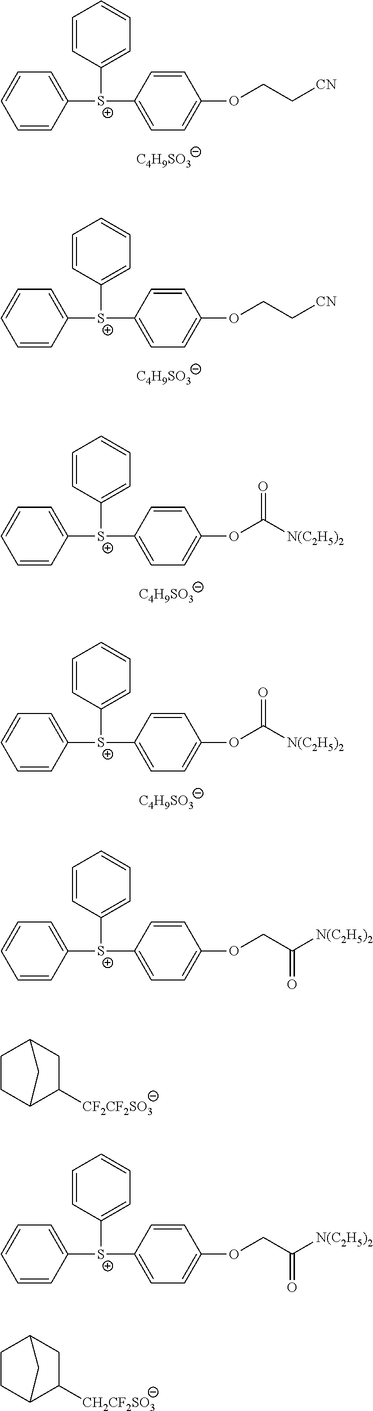

An oxime sulfonate type acid generator is a compound having at least one group represented by the formula (XIV) and is characterized by producing an acid as a result of irradiation with radiation. This type of oxime sulfonate type acid generator, which is often used as a composition for a chemically-amplified resist, may optionally be also used.

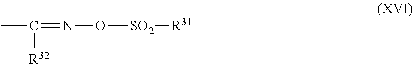

Wherein, R³¹ and R³² independently represent an organic group.

The organic groups of R³¹, R³² are groups which contain carbon atoms, and may include atoms other than carbon atoms (for example, hydrogen atoms, oxygen atoms, nitrogen atoms, sulfur atoms, halogen atoms).

The organic group R³¹ is preferably a linear or branched chain, or cyclic alkyl or aryl group. The alkyl and aryl groups may include a substituent. There is no particular limitation on the substituent, and for example, it may be a fluorine atom, a C₁ to C₆ linear or branched chain, or cyclic alkyl group.

The alkyl group preferably includes 1 to 20 carbon atoms, more preferably 1 to 10 carbon atoms, still more preferably 1 to 8 carbon atoms, yet more preferably 1 to 6 carbon atoms, and most preferably 1 to 4 carbon atoms. It is particularly preferred that the alkyl group is a partially or completely halogenated alkyl group (hereafter, this may be referred to as a halogenated alkyl group). A partially halogenated alkyl group means an alkyl group in which a part of the hydrogen atoms are substituted by halogen atoms, and a completely halogenated alkyl group means an alkyl group in which all the hydrogen atoms are substituted by halogen atoms. The halogen atom includes a fluorine atom, a chlorine atom, a bromine atom, and an iodide atom, and a fluorine atom is particularly preferred. In other words, the halogenated alkyl group is preferably a fluorinated alkyl group.

The aryl group preferably includes 4 to 20 carbon atoms, more preferably 4 to 10 carbon atoms, and most preferably 6 to 10 carbon atoms. It is particularly preferred that the aryl group is a partially or completely halogenated aryl group.

It is particularly preferred that the R³¹ is a non-substituted C₁ to C₄ alkyl group or a C₁ to C₄ fluorinated alkyl group.

The organic group of R³² is preferably a linear and branched chain, or cyclic alkyl group, aryl group or cyano group. The alkyl or aryl group of R³² is the same as the alkyl or aryl group of R³¹.

It is particularly preferred that the R³² is a cyano group, a non-substituted C₁ to C₈ alkyl or a C₁ to C₈ fluorinated alkyl group.

The oxime sulfonate type acid generator is preferably a compound represented by the formula (XVII) or (XVIII).

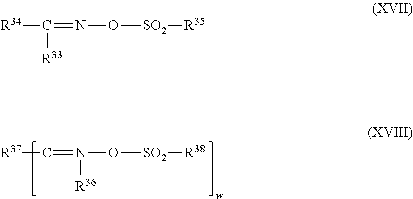

In the formula (XVII), R³³ represents a cyano group, a non-substituted alkyl group or a halogenated alkyl group. R³⁴ represents an aryl group. R³⁵ represents a non-substituted alkyl group or a halogenated alkyl group.

In the formula (XVIII), R³⁶ represents a cyano group, a non-substituted alkyl group or a halogenated alkyl group. R³⁷ represents a divalent or trivalent aromatic hydrocarbon group. R³⁸ represents a non-substituted alkyl group or a halogenated alkyl group. w is 2 or 3, and preferably is 2.

In the formula (XVII), the non-substituted alkyl group or the halogenated alkyl group of R³³ preferably has 1 to 10 carbon atoms, more preferably 1 to 8 carbon atoms and most preferably 1 to 6 carbon atoms.

R³³ is preferably a halogenated alkyl group, and more preferably a fluorinated alkyl group.

It is preferred that 50% or more of the hydrogen atoms in the alkyl groups in the fluorinated alkyl group of R³³ are fluorinated, more preferably 70% or more, and further preferably 90% or more. It is most preferred that it is a completely fluorinated alkyl group in which 100% of the hydrogen atoms are substituted. This is in order to increase the strength of the resulting acid.

The aryl group of R³⁴ includes a group in which one hydrogen atom is removed from the aromatic hydrocarbon ring, a heteroaryl group in which a part of the carbon atoms forming the ring of such groups is replaced by a hetero atom such as an oxygen atom, a sulfur atom, or a nitrogen atom. Among these, a fluorenyl group is preferred.

The aryl group of R³⁴ may include substituent such as a C₁ to C₁₀ alkyl group, a halogenated alkyl group or an alkoxy group. The alkyl group or the halogenated alkyl group in the substituent preferably has 1 to 8 carbon atoms, and more preferably 1 to 4 carbon atoms. The halogenated alkyl group is preferably a fluorinated alkyl group.

The non-substituted alkyl group or the halogenated alkyl group in R³⁵ is exemplified by the same examples as described in above R³³.

In the formula (XVIII), the non-substituted alkyl group or the halogenated alkyl group in R³⁶ is the same examples as described in above R³³.

The divalent or trivalent aromatic hydrocarbon group in R³⁷ includes a group in which a further one or two hydrogen atoms are removed from the aryl group in above R³⁴.

The non-substituted alkyl group or the halogenated alkyl group in R³⁸ is the same as described in above R³⁵.

The oxime sulfonate type acid generator includes a compound discussed in paragraph [0122] of JP2007-286161-A, the oxime sulfonate type acid generators disclosed in [Chem.18] to [Chem.19] in paragraphs [0012] to [0014] of JPH09-208554-A, and the oxime sulfonate type acid generators disclosed in Example 1 to 40 on pages 65 to 85 of WO2004/074242A2.

The following examples are preferred.

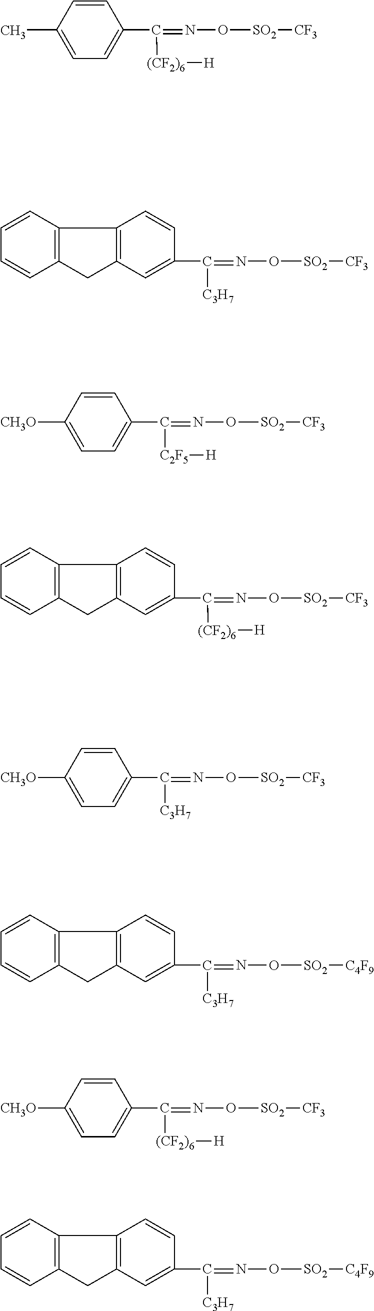

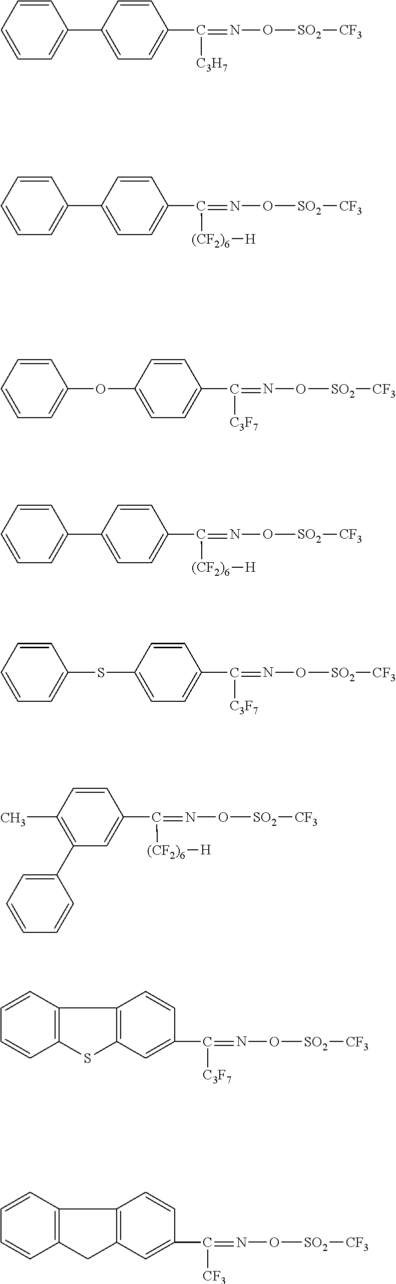

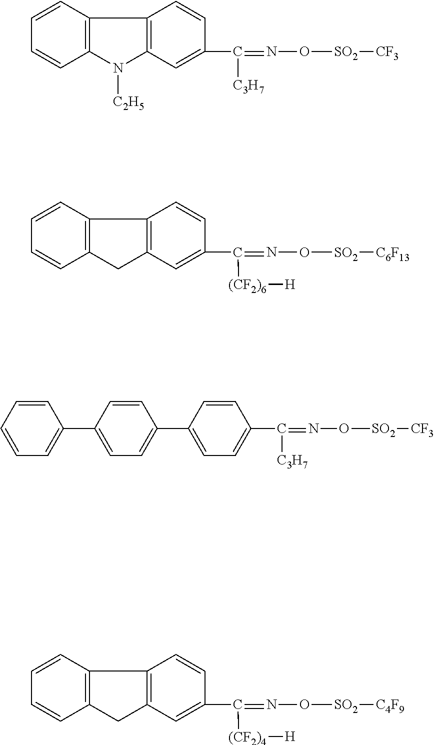

Types of bisalkyl or bisaryl sulfonyl diazomethane among the diazomethane acid generators include bis(isopropylsulfonyl)diazomethane, bis (p-toluene sulfonyl)diazomethane, bis(1,1-dimethylethyl sulfonyl)diazomethane, bis(cyclohexyl sulfonyl)diazomethane and bis (2, 4-dimethylphenyl sulfonyl)diazomethane.

The diazomethane type acid generators disclosed in JPH11-035551-A, JPH11-035552-A, and JPH11-035573-A may also be suitably used.

Types of poly(bis-sulfonyl)diazomethane include, for example, 1,3-bis(phenylsulfonyl diazomethylsulfonyl)propane, 1,4-bis(phenylsulfonyl diazomethylsulfonyl)butane, 1,6-bis(phenylsulfonyl diazomethylsulfonyl)hexane, 1,10-bis(phenylsulfonyl diazomethylsulfonyl)decane, 1,2-bis(cyclohexylsulfonyl diazomethylsulfonyl)ethane, 1,3-bis(cyclohexylsulfonyl diazomethylsulfonyl)propane, 1,6-bis(cyclohexylsulfonyl diazomethylsulfonyl)hexane, 1,10-bis(cyclohexylsulfonyl diazomethylsulfonyl)decane, as disclosed in JPH11-322707-A.

Among these, an onium salt having an anion formed from a fluorinated alkyl sulfonic acid ion is preferably used as a component of (B2).

In the present invention, the photo acid generator may be used singly or in a mixture of two or more agents.

The resist composition used in the present invention with reference to total solid content preferably contains about 70 to 99.9 wt % of the resin (A), about 0.1 to 30 wt %, preferably about 0.1 to 20 wt %, and more preferably about 1 to 10 wt % of the photo acid generator. This range enables sufficient execution of pattern forming in addition to obtaining homogenous solution and excellent storage stability.

There is no particular limitation on the cross-linking agent (C) and the agent may be suitably selected from cross-linking agents used in this field.

Examples include a compound produced by reacting formaldehyde, or formaldehyde and a lower alcohol with a compound containing an amino group such as acetoguanamine, benzoguanamine, urea, ethylene urea, propylene urea, and glycoluril, and replacing hydrogen atoms in the amino group by a hydroxymethyl group or a lower alkoxy methyl group; or an aliphatic hydrocarbon having two ore more ethylene oxide structural moiety. A compound using urea is hereinafter termed a urea cross-linking agent, a compound using an alkylene urea such as ethylene urea and propylene urea is hereinafter termed an alkylene urea cross-linking agent, and a compound using glycoluril is hereinafter termed a glycoluril cross-linking agent. Among these, urea cross-linking agents, alkylene urea cross-linking agents and glycoluril cross-linking agents are preferred, and glycoluril cross-linking agents are more preferred.

A urea cross-linking agent includes a compound in which urea is reacted with formaldehyde, and the hydrogen atoms in the amino group are replaced by a hydroxymethyl group, or a compound in which urea, formaldehyde and a lower alcohol are reacted, and the hydrogen atoms in the amino group are replaced by a lower alkoxy methyl group. Specific examples include bis(methoxymethyl)urea, bis(ethoxymethyl)urea, bis(propoxymethyl)urea, and bis(butoxymethyl)urea. Among these, bis(methoxymethyl)urea is preferred.

The alkylene urea cross-linking group includes a compounds represented by the formula (XIX).

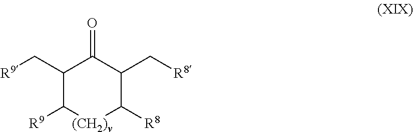

wherein R⁸ and R⁹ independently represent a hydroxyl group or a lower alkoxy group, R^{8′} and R^{9′} independently represent a hydrogen atom, a hydroxyl group or a lower alkoxy group, and v is 0 or an integer of 1 to 2.

When R^{8′} and R^{9′} are a lower alkoxy group, the alkoxy group preferably has 1 to 4 carbon atoms and may be linear or branched chain. R^{8′} and R^{9′} may be the same, or may be different. It is more preferred that R^{8′} and R^{9′} are the same.

When R⁸ and R⁹ are a lower alkoxy group, the alkoxy group preferably has 1 to 4 carbon atoms and may be linear of branched chain. R⁸ and R⁹ may be the same, or may be different. It is more preferred that R⁸ and R⁹ are the same.

v is 0 or an integer of 1 to 2, and is preferably 0 or 1.

It is particularly preferred that the alkylene urea cross-linking agent is a compound in which v is 0 (an ethylene urea cross-linking agent) and/or a compound in which v is 1 (a propylene urea cross-linking agent).

A compound represented by the formula (XIII) above can be obtained by a condensation reaction of alkylene urea and formalin, or by reacting the resulting product with a lower alcohol.

Specific examples of an alkylene urea cross-linking agent include ethylene urea cross-linking agents such as mono- and/or di-hydroxymethylated ethylene urea, mono- and/or di-methoxymethylated ethylene urea, mono- and/or di-ethoxymethylated ethylene urea, mono- and/or di-propoxymethylated ethylene urea, and mono- and/or di-butoxymethylated ethylene urea; and propylene urea cross-linking agents such as mono- and/or di-hydroxymethylated propylene urea, mono- and/or di-methoxymethylated propylene urea, mono- and/or di-ethoxymethylated propylene urea, mono- and/or di-propoxymethylated propylene urea, and mono- and/or di-butoxymethylated propylene urea; 1,3-di(methoxymethyl)-4,5-dihydroxy-2-imidazolidinone and 1,3-di(methoxymethyl)-4,5-dimethoxy-2-imidazolidinone.

Examples of glycoluril cross-linking agents include a glycoluril derivative in which the N-position is substituted with either or both a hydroxyalkyl group and/or a C₁ to C₄ alkoxyalkyl group. The glycoluril derivative can be obtained by subjecting a glycoluril and formalin to a condensation reaction, or by further reacting the product of this reaction with a lower alcohol.

Specific examples of glycoluril cross-linking agents include mono-, di-, tri- or tetra-hydroxymethylated glycoluril, mono-, di-, tri- and/or tetra-methoxymethylated glycoluril, mono-, di-, tri- and/or tetra-ethoxymethylated glycoluril, mono-, di-, tri- and/or tetra-propoxymethylated glycoluril, and mono-, di-, tri- and/or tetra-butoxymethylated glycoluril.

The cross-linking agent (C) may be used singly or in a combination of two or more agents.

The content of the cross-linking agent (C) is preferably 0.5 to 30 parts by mass relative to 100 parts by mass of the resin (A) component, and more preferably 0.5 to 10 parts by mass, and still more preferably 1 to 5 parts by mass. The formation of cross-linking is sufficiently promoted within this range and obtains a superior resist pattern. Furthermore storage stability of the resist coating liquid is superior and deterioration over time of its sensitivity can be suppressed.

The resist compound used in the present invention preferably contains a thermal acid generator (D).

A thermal acid generator as used herein refers a compound which is stable at a temperature which is lower than a hard bake temperature (as described hereafter) for a resist which uses the thermal acid generator, but decomposes at greater than or equal to the hard bake temperature and thereby produces acids. In contrast, the photo acid generator is stable at a pre-bake temperature (as described hereafter) or a post-exposure bake temperature (as described hereafter) and produces acids as a result of exposure. This distinction can be obtained fluidly depending on the aspect in which the present invention is used. That is to say, it can function as both a thermal acid generator and a photo acid generator depending on the applied processing temperature, or may only function as a photo acid generator, in the same resist. Although it does not function as a thermal acid generator in a certain resist, it may function as a thermal acid generator in another resist.

The thermal acid generator includes various known thermal acid generators such as benzoin tosylate, nitrobenzyl tosylate (in particular, 4-nitrobenzyl tosylate), and other alkylesters of organic sulfonic acids.

The content of the thermal acid generator (D) preferably be 0.5 to 30 parts by mass relative to 100 parts by mass of the resin (A), more preferably 0.5 to 15 parts by mass, and most preferably 1 to 10 parts by mass.

The resist composition of the present invention may include a basic compound, preferably a nitrogen-containing basic compound, in particular, an amine or an ammonium salt is preferable. The basic compound can be added as a quencher to improve performance from being compromised by the inactivation of the acid while the material is standing after exposure. When the basic compound is used, the content thereof is preferably 0.01 to 1 weight % with reference to total solid content of the resist composition.

The examples of such basic compounds include those represented by the following formulae.

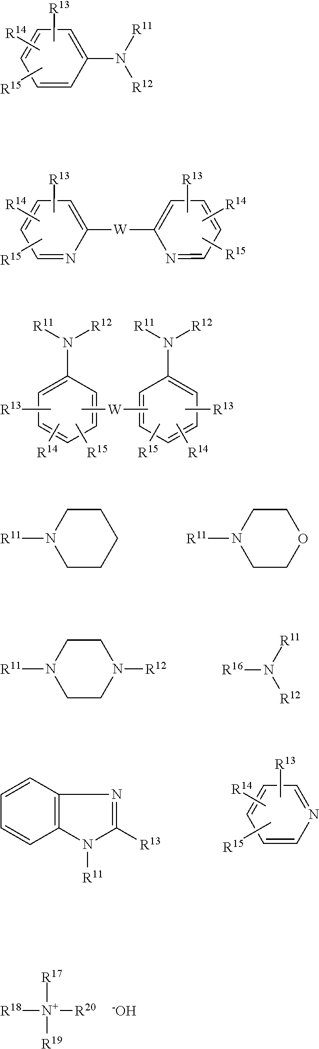

wherein R¹¹ and R¹² independently represent a hydrogen atom, an alkyl group, a cycloalkyl group or an aryl group, the alkyl group preferably has about 1 to 6 carbon atoms, the cycloalkyl group preferably has about 5 to 10 carbon atoms, the aryl group preferably has about 6 to 10 carbon atoms;

R¹³, R¹⁴ and R¹⁵ independently represent a hydrogen atom, an alkyl group, a cycloalkyl group, an aryl group or an alkoxy group, the alkyl group, the cycloalkyl group, and the aryl group are the same as described in R¹¹ and R¹², the alkoxy group preferably has 1 to 6 carbon atoms.

R¹⁶ represents an alkyl group or a cycloalkyl group, the alkyl group and the cycloalkyl group are the same as described in R¹¹ and R¹².

R¹⁷, R¹⁸, R¹⁹ and R²⁰ independently represent an alkyl group, a cycloalkyl group or an aryl group, the alkyl group, the cycloalkyl group and the aryl group are the same as described in R¹¹, R¹² and R¹⁷.

Further, at least one hydrogen atom in the alkyl group, the cycloalkyl group and the alkoxy group may be independently replaced by a hydroxyl group, an amino group or a C₁ to C₆ alkoxy group. At least one hydrogen atom in the amino group may be replaced by a C₁ to C₄ alkyl group.

W represents an alkylene group, a carbonyl group, an imino group, a sulfide group or a disulfide group. The alkylene group preferably has about 2 to 6 carbon atoms.

In R¹¹ to R²⁰, if the group may be linear or branched chain, either one is included.

Examples of such compounds include a compound disclosed in JP-2006-257078-A.

Furthermore, hindered amine compounds with a piperidine skeleton such as those disclosed in JP-11-52575-A can be used as a quencher.

The resist composition used in the present invention may also include various additives known in this field such as sensitizers, dissolution inhibitors, other resins, surfactants, stabilizers and dyes, as needed.

The resist composition used in the present invention is normally used as a resist liquid composition in a state in which each component is dissolved in a solvent. This type of resist composition is used at least as a first resist composition. In this manner, it is possible to use a so-called double imaging method. In the double imaging method, a fine resist pattern can be obtained that has half the pattern pitch by twice repeating the process of resist coating, exposure and development. This type of process may be repeated a plurality of three or more times (N times). In this manner, a finer resist pattern having a pattern pitch of 1/N can be obtained. The present invention can be suitably applied to this type of double, triple imaging method and multi-imaging method.

The above resist composition may be used as a second resist composition. In this case, there is no necessity for the composition to always be the same as the first resist composition.

In the resist processing method of the present invention, firstly the resist liquid composition described above (hereafter may be referred to as the first resist composition) is coated on to a substrate and dried thereby obtaining a first resist film. There is no particular limitation on the thickness of the first resist film, and the thickness are suitably set with reference to a direction of film thickness to substantially equal to or less than a level sufficiently enabling exposure and developing during following steps, and for example, may be of the level of several tenths of micrometers to several millimeters.

There is no particular limitation on the substrate and for example various materials may be used including a semiconductor substrate such as a silicon wafer, a plastic, metal or ceramic substrate, a substrate having an insulating film or conducting layer thereon.

There is no particular limitation on the method of coating the composition and a method used in normal industrial processing such as spin coating may be used.

Any substance can be used as a solvent used to obtain the resist liquid composition as long as the substance dissolves each component, has a suitable drying speed and obtains a flat uniform coating after evaporation of the solvent. Normally-used general solvents in this area may be applied.

Examples thereof include glycol ether esters such as ethylcellosolve acetate, methylcellosolve acetate and propylene glycol monomethyl ether acetate; glycol ethers such as propylene glycol monomethyl ether; esters such as ethyl lactate, butyl acetate, amyl acetate and ethyl pyruvate; ketones such as acetone, methyl isobutyl ketone, 2-heptanone and cyclohexanone; and cyclic esters such as y-butyrolactone. These solvents can be used alone or in combination of two or more.

The drying process includes natural drying, draft drying, and reduced pressure drying. The specific heating temperature may be about 10 to 120° C., and more preferably about 25 to 80° C. The heating period is about 10 seconds to 60 minutes and preferably about 30 seconds to 30 minutes.

Next, the resulting first resist film is pre-baked. The pre-baking is conducted for example in a temperature range of about 80 to 140° C. and in the range of about 30 seconds to 10 minutes. Then an exposure process for patterning is executed. The exposure process is preferably carried out using any exposure device that is generally used in this field such as a scanning exposure type, i.e., a scanning stepper type projection exposure device (exposure device). Various types of exposure light source can be used, such as irradiation with ultraviolet lasers such as KrF excimer laser (wavelength: 248 nm), ArF excimer laser (wavelength: 193 nm), F₂ laser (wavelength: 157 nm), or irradiation with harmonic laser light of far-ultraviolet wavelength or vacuum ultraviolet wavelength which is converted from a solid-state laser source (YAG or semiconductor laser or the like).

Thereafter, the resulting first resist film is post-exposure baked. This heating process can promote a protection deblocking reaction. The heating process for example is executed at a temperature range of about 70 to 140° C. and for the range of about 30 seconds to 10 minutes.

Then, a first resist film is developed with a first alkali developer. The alkali developer includes various types of aqueous alkali solutions used in this field, and normally an aqueous solution such as tetramethylammonium hydroxide(2-hydroxyethyl)trimethylammonium hydroxide (common name: choline) is used.

The obtained first resist pattern is hard-baked. This heating process can promote cross-linking reactions. The hard-baking herein is executed by at least two steps, i.e. maintaining a temperature lower than the glass-transition temperature of the first resist composition for a predetermined period of time, and then maintaining a temperature not lower than such glass-transition temperature (preferably higher than the glass-transition temperature) for a predetermined period of time.

There is no particular limitation on the temperature (X1) lower than the glass-transition temperature of the first resist composition (T). It is, for example, a temperature of

T-20° C.≦X1<T.

From another stand point, a temperature range of about 100 to 180° C. is preferred since the above resist composition generally has a glass-transition temperature of about 120 to 200° C. There is no particular limitation on the period of time during which such temperature is to be maintained. Preferably, about 30 seconds to 2 minutes is suitable. Further, the temperature is preferably maintained at a constant while the temperature is being maintained.

There is no particular limitation on the temperature (X2) not lower than the glass-transition temperature of the first resist composition (T). It is, for example, a temperature of

T≧X2≧T+20° C.

From another stand point, a temperature range of higher than 120° C. and not higher than 200° C. is preferred since the above resist composition has a glass-transition temperature of about 120 to 200° C. There is no particular limitation on the period of time during which such temperature is to be maintained. Preferably, about 30 seconds to 5 minutes is suitable. Further, the temperature may be varied in the range of higher than the glass-transition temperature while the temperature is being maintained. However, the temperature is preferably maintained at a constant.

By performing the hard-baking in such two steps, baking at a relatively low temperature in the first step can promote cross-linking reactions in a resist composition, and a rise in the glass-transition temperature of the entire resist composition is expected. Consequently, it is considered that softening of the resist composition and dripping of the resin do not occur during the baking at a relatively high temperature in the second step, and a good resist pattern can be formed and a good resist pattern can be maintained also in the subsequent steps of resist pattern.

This temperature change in hard-baking may be conducted in a way in which, for example, a temperature may be raised from the temperature (X1) to the temperature (X2) directly, or a temperature may be raised to the temperature (X2) subsequent to a step such as brief cooling after being maintained at the temperature (X1). That is, a substrate on which the first resist composition is formed may be moved from the temperature (X1) chamber to the temperature (X2) chamber directly. Or it may be taken out from the temperature (X1) chamber before being introduced into the temperature (X2) chamber, or it may be placed on a plate at the temperature (X1), followed by baking and then placed on a plate at the temperature (X2).

Furthermore, a second resist composition is coated on the first resist pattern formed using the resist composition above and dried to thereby form a second resist film. This is pre-baked, and subjected to exposure processing for patterning. An arbitrary heating process, a post-exposure bake is usually performed. Thereafter, a second resist pattern can be formed by developing with a second alkali developer.

The conditions for coating, drying, pre-baking, exposure and post-exposure baking with respect to the second resist composition are the same as those conditions described with reference to the first resist composition.

There is no particular limitation on the second resist composition, and either a negative or a positive resist composition may be used and any known composition used in this field may be used. Any of the resist compositions described above may be used and in that case, it is not necessary always the same composition as the first resist composition.

In the present invention, even with a double imaging method including at least two exposures and developing processes and multiple heating processes, a first resist film is used which retains an original shape and does not cause deformation of the pattern itself and therefore, it is possible to create an extremely fine pattern.

### EXAMPLES

The resist composition of the present invention will be described more specifically by way of examples. All percentages and parts expressing the content or amounts used in the Examples are based on weight, unless otherwise specified. The weight average molecular weight is a value determined by gel permeation chromatography

Column: TSKgel Multipore H_{XL}-M 3 connecting+guardcolumn (Toro Co. ltd.)

Eluant: tetrahydrofran

Flow rate: 1.0 mL/min

Detecting device: RI detector

Column temperature: 40 ° C.

Injection amount: 100 μL

Standard material for calculating molecular weight: standard polysthylene (Toso Co. ltd.)

The grass-transition temperature of the resist composition was measured by a differential scanning calorimetry (DSC) (apparatus-used: Q2000 from TA Instruments Co. Ltd.)

The resist composition was spin-coated onto silicon wafers so that the thickness of the resulting film became 0.08 μm after drying, and pre-baked for 60 seconds at 95° C. on a direct hot plate. A flake which was obtained by scraping the resulting resist film off using a razor blade and the like was used as a sample.

The monomers used in synthesis of resin are follows.

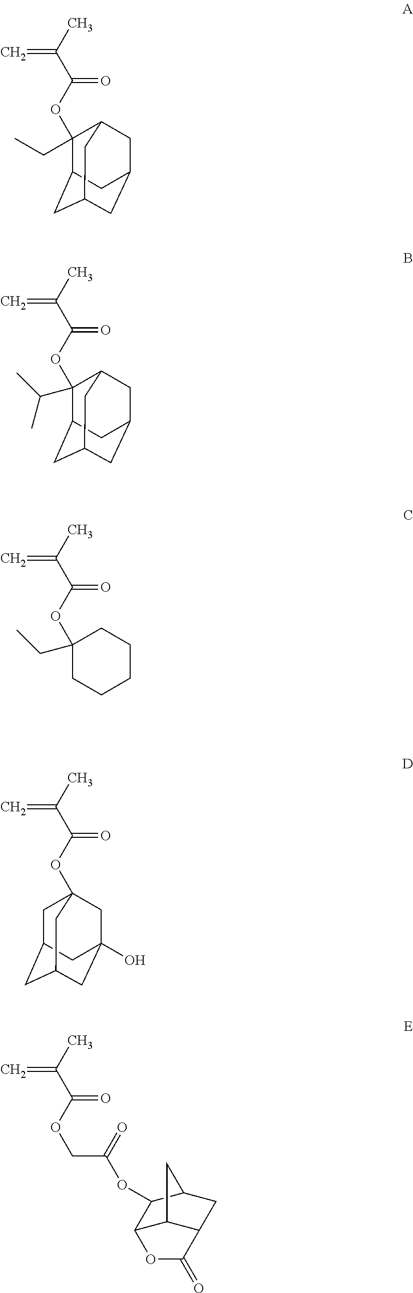

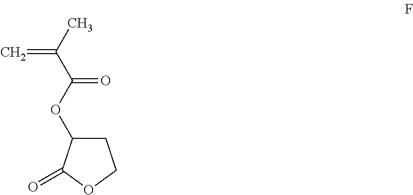

### Example of Resin Synthesis 1

### Synthesis of Resin 1

24.45 parts of 1,4 dioxane was charged in a four-neck flask provided with a thermometer and a reflux condenser and bubbled with a nitrogen gas for 30 minutes. After increasing the temperature to 73° C. under a nitrogen seal, a solution being a mixture of 15.50 parts of monomer A, 2.68 parts of C, 8.30 parts of D, 14.27 parts of F, 0.32 parts of azobisisobutyronitrile, 1.45 parts of azobis-2, 4-dimethylvaleronitrile and 36.67 parts of 1,4 dioxane was added dropwise over 2 hours while maintaining a temperature of 73° C. After completion of dropwise addition, a temperature of 73° C. was maintained for 5 hours. After cooling, the reaction solution was diluted with 44.82 parts of 1,4 dioxane. The diluted mass was poured while stirring into a mixed liquid containing 424 parts of methanol and 106 parts of an ion exchange water and a resinous precipitate was removed by filtering. The filtered material was placed in a liquid being 265 parts of methanol and filtered after stirring. The operation of placing the resulting filtrate in the similar liquid, stirring and filtering was repeated twice. Thereafter, reduced pressure drying was performed to obtain 31 parts of resin. The resin is represented as R1. The yield was 75%, Mw: 8500 and Mw/Mn: 1.80.

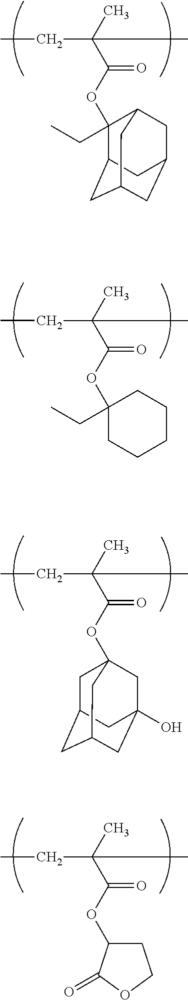

### Example of Resin Synthesis 2

### Synthesis of Resin 2

27.78 parts of 1,4 dioxane was charged in a four-neck flask provided with a thermometer and a reflux condenser and bubbled with a nitrogen gas for 30 minutes. After increasing the temperature to 73° C. under a nitrogen seal, a solution being a mixture as described in the above of 15.00 parts of monomer B, 5.61 parts of C, 2.89 parts of monomer D, 12.02 parts of E, 10.77 parts of monomer F, 0.34 parts of azobisisobutyronitrile, 1.52 parts of azobis-2, 4-dimethylvaleronitrile and 63.85 parts of 1,4 dioxane was added dropwise over 2 hours while maintaining a temperature of 73° C. After completion of dropwise addition, a temperature of 73° C. was maintained for 5 hours. After cooling, the reaction solution was diluted with 50.92 parts of 1,4 dioxane. The diluted mass was poured while stirring into 481 parts of methanol and 120 parts of ion-exchanged water, and a resinous precipitate was removed by filtering. The filtered material was placed in a liquid being 301 parts of methanol and filtered after stirring. The operation of placing the resulting filtrate in the same liquid, stirring and filtering was repeated twice. Thereafter reduced pressure drying was performed to obtain 37.0 parts of resin having structure units below. The resin is represented as R2. The yield was 80%, Mw: 7883, Mw/Mn: 1.96.

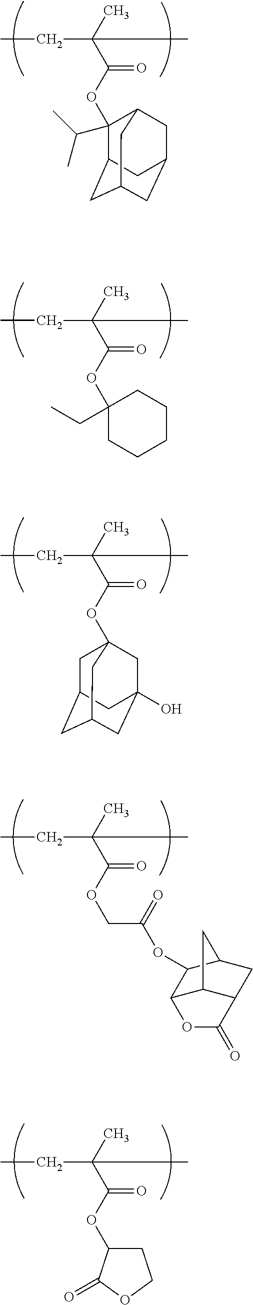

### Example of Photo Acid Generator Synthesis

### Triphenylsulfonium 1-((3-hydroxyadamantyl)methoxycarbonyl)difluoromethanesulfonate

(1) To a mixture of 100 parts of methyl difluoro(fluorosulfonyl)acetate and 150 parts of ion-exchanged water, 230 parts of 30% sodium hydroxide aqueous solution was added in the form of drops in an ice bath. The resultant mixture was refluxed for 3 hours at 100° C., cooled, and then neutralized with 88 parts of concentrated hydrochloric acid. The resulting solution was concentrated whereby giving 164.4 parts of sodium salt of difluorosulfoacetic acid (containing inorganic salt: 62.7% purity).

(2) 1.0 parts of 1,1′-carbonyldiimidazol was added to a mixture of 1.9 parts of sodium salt of difluorosulfoacetic acid (62.7% purity) and 9.5 parts of N,N-dimethylformamide, and the resultant mixture was stirred for 2 hours to obtain a mixture. The obtained mixture was added to a mixture solution in which 0.2 parts of sodium hydride was added to a mixture of 1.1 parts of 3-hydroxyadamantyl methanol and 5.5 parts of N,N-dimethylformamide, and the resultant mixture was stirred for 2 hours. The resulting mixture was stirred for 15 hours to obtain a solution containing sodium salt of ((3-hydroxy-1-adamantyl)methyl)difluorosulfoacetic acid. This salt was used as was for the next reaction.

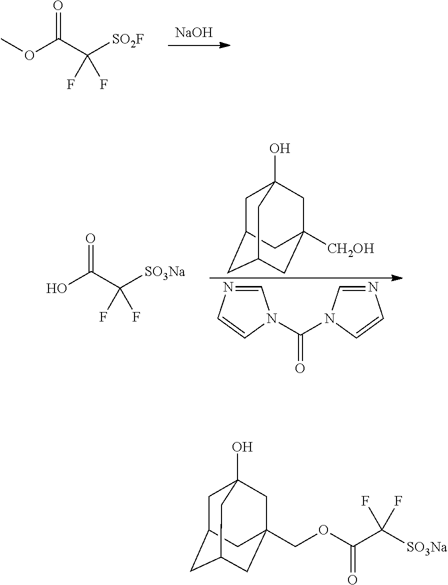

(3) To thus solution obtained in (2) and containing sodium salt of ((3-hydroxy-1-adamantyl)methyl)difluorosulfoacetic acid 17.2 parts of chloroform and 2.9 patrs of 14.8% triphenylsulfonium chloride were added, and the resulting mixture was stirred for 15 hours, and separated to obtain an organic layer. A residual water layer was extracted with 6.5 parts of chloroform to obtain an organic layer. The obtained organic layers were mixed, and washed with ion-exchanged water, and the resulting organic layer was concentrated. To the concentrate was added 5.0 parts of tert-butyl methyl ether, the resulting mixture was stirred, and filtrated whereby giving 0.2 parts of triphenylsulfonium 1-((3-hydroxyadamantyl)methoxycarbonyl)difluromethanesulfonate (Photo acid generator) in the form of a white solid.

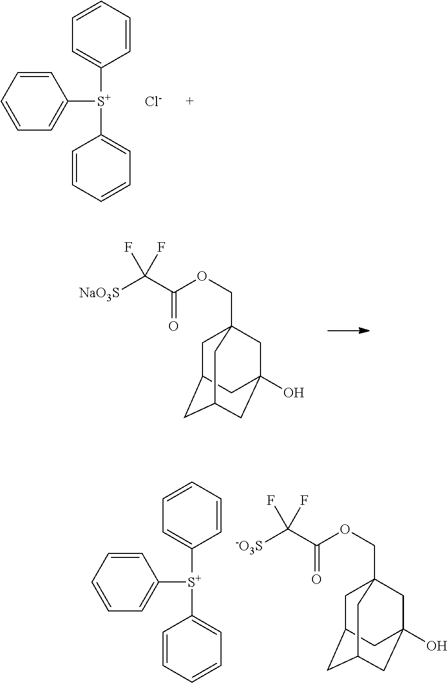

### EXAMPLES AND COMPARATIVE EXAMPLE

Resist compositions were prepared by mixing and dissolving each of the components below, and then filtering through a fluororesin filter having 0.2 μm pore diameter.

TABLE 1

| | | Photo Acid | Cross- | | Thermal Acid |
|---|---|---|---|---|---|
| | Resin | Generator | linking | | Generator |
| Ex. | (A) | (B) | Agent (C) | Quencher | (D) |
| 1 | R1 = 10 | 1.5 parts | 0.2 parts | 0.02 parts | — |
| | parts | | | | |
| 2 | R1 = 10 | 1.5 parts | 0.2 parts | 0.02 parts | 0.3 parts |
| | parts | | | | |
| Ref. | R2 = 10 | 1.5 parts | — | 0.105 parts | — |
| | parts | | | | |

The ingredients use in the Table 1 shown below.

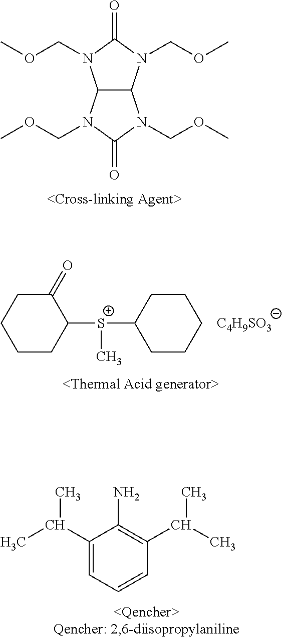

<Solvent>

| PMEG solvent 1: | | |
|---|---|---|
| Propylene glycol monomethyl ether | 180 | parts |
| 2-Heptanone | 35 | parts |
| Propylene glycol monomethyl ether acetate | 20 | parts |
| γ-butyrolactone | 3 | parts |
| PMEG solvent 2: | | |
| Propylene glycol monomethyl ether | 255 | parts |
| 2-Heptanone | 35 | parts |
| Propylene glycol monomethyl ether acetate | 20 | parts |
| γ-butyrolactone | 3 | parts |

### Example 1

Firstly, each resist composition in which the above resist compositions shown in Table 1 were dissolved in the above PMEG solvent 1 were prepared. The glass-transition temperature of Resin 1 was about 164° C., and the glass-transition temperature of the resist composition containing this Resin 1 was about 150° C.

A composition for an organic antireflective film, “ARC-29A-8”, by Brewer Co. Ltd., was applied onto silicon wafers and baked for 60 seconds at 205° C. to form a 78 nm thick organic antireflective

Each resist liquid obtained above was then applied thereon by spin coating so that the thickness of the resulting film became 0.08 μm after drying.

The application of the resist liquid was followed by 60 seconds of pre-baking at 95° C. on a direct hot plate.

A pattern were exposed at exposure value of 14 mJ/cm² by using an ArF excimer stepper (“FPA5000-AS3” by Canon: NA=0.75, 2/3 Annular) and a mask with a 100 nm line width of 1:1 line and space patterns, on the wafers on which the resist film had thus been formed.

The exposure was followed by 60 seconds of post-exposure baking at 95° C.

This was followed by 60 seconds of puddle development with 2.38 wt % tetramethylammonium hydroxide aqueous solution to form a desire pattern.

This was followed by 60 seconds of maintaining at 150° C., and elevating the temperature at 170° C. and maintaining for 60 seconds, thereby performing two-step hard-baking.

When the resulting first line and space pattern was observed using a scanning electron microscope, it was confirmed that a superior and a precisive pattern was formed.

Then a resist liquid in which the resist composition of Reference Example described in Table 1 was dissolved in the above solvent 2 as a second resist liquid was then applied on the obtained first line and space pattern so that the thickness of the resulting film became 0.08 μm after drying.

The application of the second resist liquid was followed by 60 seconds of pre-baking at 85° C. on a direct hot plate.

A second line and space pattern were exposed at exposure value of 40 mJ/cm² by using an ArF excimer stepper (“FPA5000-AS3” by Canon: NA=0.75, ⅔ Annular), so as to be in a direction perpendicular to the first line and space pattern by rotating the pattern by 90°, on the wafers on which the second resist film had thus been formed.

The exposure was followed by 60 seconds of post-exposure baking at 85° C.

This was followed by 60 sec of puddle development with 2.38 wt % tetramethylammonium hydroxide aqueous solution to form a lattice-shaped pattern definitely.

When the resulting first and second line and space pattern was observed using a scanning electron microscope, it was confirmed that the second line and space pattern was formed with a preferred shape on top of the first line and space pattern and in addition the shape of the first line and space pattern was retained and, overall, a superior pattern was formed. The profile shape was also superior.

### Example 2

An experiment was performed in the same manner as the Example 1 with the exception that a resist composition of Example 2 shown in Table 1 (glass-transition temperature: about 145° C.) was used instead of the resist composition of Example 1, and a pattern were exposed at exposure value of 11 mJ/ cm².

When the resulting first and second line and space pattern was evaluated in the same manner as the Example 1, it was confirmed that a superior pattern was as shown in Example 1.

### INDUSTRIAL APPLICABILITY

According to the resist processing method of the present invention, an extremely fine and highly accurate resist pattern can be formed which is obtained using the resist composition for forming a first resist pattern in a multi-patterning method or a multi-imaging method such as a double patterning method, double imaging method.

1. A resist processing method comprising:
(1) a step of applying a first resist composition comprising a resin (A) having an acid-labile group, being insoluble or poorly soluble in alkali aqueous solution, and being rendered soluble in alkali aqueous solution through an action of an acid, a photo acid generator (B) and a cross-linking agent (C) to obtain a first resist film;
(2) a step of prebaking the first resist film;
(3) a step of exposure processing the first resist film;
(4) a step of post-exposure baking the first resist film;
(5) a step of developing with a first alkali developer to obtain a first resist pattern;
(6) a step of hard-baking by maintaining the first resist pattern at a temperature which is lower than a glass transition temperature of the above-mentioned first resist composition for a predetermined period of time, and then maintaining the first resist pattern at a temperature which is the glass transition temperature of the first resist composition or higher for a predetermined period of time;
(7) a step of applying a second resist composition onto the first resist pattern, and then drying to obtain a second resist film;
(8) a step of pre-baking the second resist film;
(9) a step of exposure processing the second resist film;
(10) a step of post-exposure baking the second resist film; and
(11) a step of developing with a second alkali developer liquid to obtain a second resist pattern.

2. The resist processing method according to claim 1, wherein the first resist pattern is maintained at a temperature which is lower than the glass transition temperature for 60 seconds or more.

3. The resist processing method according to claim 1 or 2, wherein the maintaining the first resist pattern at a temperature which is lower than the glass transition temperature is performed at a constant temperature.

4. The resist processing method according to claim 1, wherein the cross-linking agent (C) is at least one selected from the group consisting of a urea cross-linking agent, an alkylene urea cross-linking agent and a glycoluril cross-linking agent.

5. The resist processing method according to claim 1, wherein the content of the cross-linking agent (C) is 0.5 to 30 parts by mass relative to the resin (A) 100 parts by mass.

6. The resist processing method according to claim 1, wherein the acid-labile group of the resin (A) is a group having an alkyl ester group or lactone ring, in which a carbon atom that bonds to an oxygen atom of —COO— is a quaternary carbon atom, or a group having a carboxylate.

7. The resist processing method according to claim 1, wherein the photo acid generator (B) is a compound represented by the formula (I). 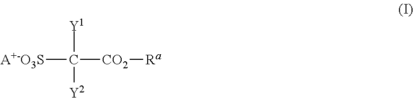
wherein, R^{a} is a C₁ to C₆ linear or branched chain hydrocarbon group, or a C₃ to C₃₀ cyclic hydrocarbon group, when R^{a} is a cyclic hydrocarbon group, the cyclic hydrocarbon group may be substituted with one or more selected from the group consisting of a C₁ to C₆ alkyl group, a C₁ to C₆ alkoxy group, a C₁ to C₄ perfluoroalkyl group, an ether group, an ester group, a hydroxyl group and a cyano group;
A⁺ represents an organic counter ion; and
Y¹ and Y² independently represent a fluorine atom or a C₁ to C₆ perfluoroalkyl group.

8. The resist processing method according to claim 1, wherein the photo acid generator (B) is a compound represented by the formula (V) or the formula (VI). 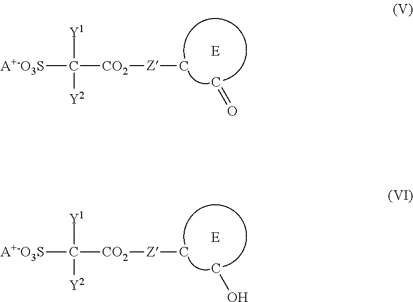
wherein a ring E represents a C₃ to C₃₀ cyclic hydrocarbon group, the ring E may be substituted with one or more selected from the group consisting of a C₁ to C₆ alkyl group, a C₁ to C₆ alkoxy group, a C₁ to C₄ perfluoroalkyl group, a C₁ to C₆ hydroxyalkyl group, a hydroxyl group and a cyano group;
Z′ represents a single bond or a C₁ to C₄ alkylene group; and
A⁺, Y¹ and Y² have the same meaning as defined above.

9. The resist processing method according to claim 1, wherein the photo acid generator (B) is a compound containing one or more cations selected from the group consisting of the formulae (IIa), (IIb), (IIc), (IId) and (IV). 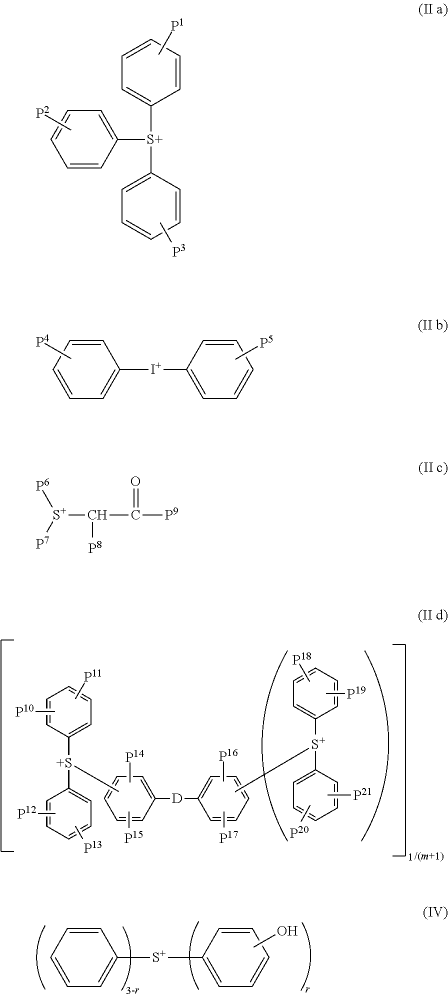
wherein P¹ to P⁵ and P¹⁰ to P²¹ independently represent a hydrogen atom, a hydroxyl group, a C₁ to C₁₂ alkyl group or a C₁ to C₁₂ alkoxy group;
P⁶ and P⁷ independently represent a C₁ to C₁₂ alkyl group or a C₃ to C₁₂ cycloalkyl group, or P⁶ and P⁷ are bonded to represent a C₃ to C₁₂ divalent hydrocarbon group;
P⁸ represents a hydrogen atom;
P⁹ represents a C₁ to C₁₂ alkyl group, a C₃ to C₁₂ cycloalkyl group or an optionally substituted aromatic group, or P⁸ and P⁹ are bonded to represent a C₃ to C₁₂ divalent hydrocarbon group;
D represents a sulfur atom or an oxygen atom; and
m represents 0 or 1; and
r represents an integer of 1 to 3.

10. The resist processing method of according to claim 1, which further comprises a thermal acid generator (D).
